(19) United States
(12) Patent Application Publication
(10) Pub. No.: US 2025/0107304 A1
(43) Pub. Date: Mar. 27, 2025

(54) DISPLAY DEVICE

(71) Applicant: Samsung Display Co., LTD., Yongin-si (KR)

(72) Inventors: Sunhwa LEE, Yongin-si (KR); Hyeongseok KIM, Yongin-si (KR); Heejean PARK, Yongin-si (KR); Mukyung JEON, Yongin-si (KR)

(21) Appl. No.: 18/891,206

(22) Filed: Sep. 20, 2024

(30) Foreign Application Priority Data
Sep. 22, 2023 (KR) 10-2023-0127291

(51) Int. Cl. H01L 33/62; G09G 3/32

(52) U.S. Cl. CPC H10H 20/857; G09G 3/32; G09G 2310/0275; G09G 2380/02

(57) ABSTRACT

A display device including a display area and a non-display area, where the non-display area includes a first area disposed on one side of the display area and a second area between the display area and the first area. The display device includes a first portion arranged in the first area, a plurality of first island portions arranged in the second area and spaced apart from each other, a plurality of second island portions each arranged over the first area and the second area, and a plurality of bridge portions each connecting two adjacent island portions among the plurality of first island portions and the plurality of second island portions, wherein the plurality of bridge portions are spaced apart from each other by a plurality of first openings. The plurality of second island portions are provided integrally with the first portion.

This application claims priority to Korean Patent Application No. 10-2023-0127291, filed on Sep. 22, 2023, and all the benefits accruing therefrom under 35 U.S.C. § 119, the content of which in its entirety is herein incorporated by reference.

### BACKGROUND

### 1. Field

One or more embodiments relate to a display device, for example, a flexible display device.

### 2. Description of the Related Art

With the development of display devices that visually display electrical signals, various display devices having excellent characteristics such as thinness, weight reduction, and low power consumption have been introduced. For example, flexible display devices that can be folded or rolled into a roll shape have been introduced. Recently, research and development of stretchable display devices that can change into various forms are actively underway.

### SUMMARY

One or more embodiments include a display device, for example, a flexible display device. Additional aspects will be set forth in part in the description which follows and, in part, will be apparent from the description, or may be learned by practice of the presented embodiments of the disclosure.

According to one or more embodiments, a display device including a display area and a non-display area including a first area disposed on one side of the display area and a second area between the display area and the first area includes: a first portion arranged in the first area, first island portions arranged in the second area and spaced apart from each other, second island portions each arranged over the first area and the second area, and bridge portions each connecting two adjacent island portions of the first island portions and the second island portions and spaced apart from each other by first openings, where the second island portions are provided integrally with the first portion.

The display device may further include a data driving circuit arranged in the first area, and a fan-out line extending from the data driving circuit toward the display area.

The display device may further include a data line extending from the display area to the second area, and a connection line electrically connecting the data line to the fan-out line, where the data line may be connected to the connection line in the second island portion. The connection line may be disposed in the same layer as the data line and is provided integrally with the data line.

The first portion, the second island portions, and bridge portions connecting the second island portions among the bridge portions may define second opening therebetween, and the second openings may have a different shape from the first openings.

A separation distance between the first portion and a bridge portion adjacent to the first portion among the bridge portions may be equal to a separation distance between the bridge portion and the second island portion adjacent to the bridge portion among the second island portions.

A length of the second island portion in a first direction from the second area toward the first area may be greater than a length of the first island portion in the first direction.

The bridge portion may have a serpentine shape, and a length of the second island portion in a second direction perpendicular to the first direction may be greater than a width of the bridge portion.

The data line may be arranged in a straight or diagonal line with respect to a first direction from the second area toward the first area in the second island portion.

The display device may further include main island portions arranged in the display area, and main bridge portions each connecting adjacent main island portions and spaced apart from each other by main openings, where at least some of the main island portions may each include a light-emitting element and a pixel circuit driver electrically connected to the light-emitting element, and the data line may be electrically connected to the pixel circuit driver.

The first portion may have an area corresponding to the first area.

According to one or more embodiments, a display device including a display area and a non-display area including a first area disposed on one side of the display area and a second area between the display area and the first area includes a data driving circuit arranged in the first area, a fan-out line extending from the data driving circuit toward the display area, a data line extending from the display area to the second area, a first portion arranged in the first area, first island portions arranged in the second area and spaced apart from each other, second island portions each arranged over the first area and the second area, and bridge portions each connecting two adjacent island portions of the first island portions and the second island portions and spaced apart from each other by first openings, where the second island portions are provided integrally with the first portion. The display device may further include a connection line electrically connecting the data line to the fan-out line, where the data line may be connected to the connection line in the second island portion.

The first portion, the second island portions, and bridge portions connecting the second island portions among the bridge portions may define second opening therebetween, and the second openings may have a different shape from the first openings.

A separation distance between the first portion and a bridge portion adjacent to the first portion among the bridge portions may be equal to a separation distance between the bridge portion and the second island portion adjacent to the bridge portion among the second island portions.

A length of the second island portion in a first direction from the second area toward the first area may be greater than a length of the first island portion in the first direction.

The bridge portion may have a serpentine shape, and a length of the second island portion in a second direction perpendicular to the first direction may be greater than a width of the bridge portion.

The data line may be arranged in a straight or diagonal line with respect to a first direction from the second area toward the first area in the second island portion.

The display device may further include main island portions arranged in the display area, and main bridge portions each connecting adjacent main island portions and spaced apart from each other by main openings, where at least some of the main island portions may each include a light-emitting element and a pixel circuit driver electrically connected to the light-emitting element, and the data line may be electrically connected to the pixel circuit driver.

The first portion may have an area corresponding to the first area.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view schematically showing a display device according to an embodiment;

FIGS. 2A and 2B are perspective views showing the display device of FIG. 1 stretched in a first direction;

FIG. 2C is a perspective view showing the display device of FIG. 1 stretched in a second direction;

FIG. 2D is a perspective view showing the display device of FIG. 1 stretched in the first and second directions;

FIG. 2E is a perspective view showing the display device of FIG. 1 stretched in a third direction;

FIGS. 3A and 3B are plan views schematically showing a display device according to an embodiment;

FIG. 4A is an enlarged plan view of an area IV of FIG. 3A as a portion of a display device according to an embodiment;

FIG. 4B is an enlarged plan view of an area IV of FIG. 3A as a portion of a display device according to another embodiment;

FIG. 4C is an enlarged plan view of an area IV of FIG. 3A as a portion of a display device according to still another embodiment;

FIG. 5 is a cross-sectional view schematically showing a first island portion and a first bridge portion disposed in a display area of a display device according to an embodiment;

FIGS. 6A to 6C are equivalent circuit diagrams of a sub-pixel of a display device according to an embodiment;

FIGS. 7A and 7B are cross-sectional views schematically showing a light-emitting element of a display device according to an embodiment;

FIG. 8A is an enlarged plan view of an area V of FIG. 3B as a portion of a display device according to an embodiment;

FIG. 8B is an enlarged plan view of an area A of FIG. 8A as a portion of a display device according to an embodiment;

FIG. 9 is a plan view showing an area B of FIG. 8A as a portion of a display device according to an embodiment;

FIG. 10 is a plan view showing the area B of FIG. 8A as a portion of a display device according to another embodiment; and

FIGS. 11A to 11G are perspective views schematically showing embodiments of an electronic device including a display device according to an embodiment.

### DETAILED DESCRIPTION

Reference will now be made in detail to embodiments, examples of which are illustrated in the accompanying drawings, where like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

The disclosure is subject to various modifications and may have many embodiments, certain of which are illustrated in the drawings and further described in the detailed description. The effects and features of the disclosure, and methods of achieving them will become clear with reference to the embodiments described below in detail together with the drawings. However, the disclosure is not limited to the embodiments described herein and may be implemented in various forms.

In the following embodiments, the terms “first”, “second”, etc. are not intended to be limiting, however are used to distinguish one component from another.

In the following embodiments, the singular expression includes the plural unless the context clearly indicates otherwise.

It will be further understood that the terms “include” and/or “have” used herein specify the presence of stated features or components, but do not preclude the presence or addition of one or more other features or components.

In the following embodiments, when a portion of a film, area, component, etc. is the to be over or on top of another portion, this includes not only when it is directly on top of the other portion, but also when there are other films, areas, components, etc. arranged therebetween.

In the specification, the expression such as “A and/or B” may include A, B, or A and B. Furthermore, the expression such as “at least one of A and B” may include A, B, or A and B.

As used herein, when a wiring is referred to as “extending in a first direction or a second direction,” it means that the wiring not only extends in a straight line shape but also extends in a zigzag or in a curve in the first direction or the second direction.

As used herein, “in a plan view” means that an objective portion is viewed from above, and “in a cross-sectional view” means that a cross-section of an objective portion taken vertically is viewed from a lateral side. In the following embodiments, when referring to “overlapping”, this includes overlapping “in a plan view” and overlapping “in a cross-sectional view”.

Hereinafter, embodiments will be described in detail with reference to the accompanying drawings, and when being described with reference to the drawings, the same or corresponding components are given the same reference numerals.

In the drawings, components may be exaggerated or reduced in size for ease of illustration. For example, the size and thickness of each configuration shown in the drawings are arbitrary for purposes of illustration and the disclosure is not necessarily limited to those shown.

In some embodiments, a particular sequence of processes may be performed in a different order than that described. For example, two processes described in succession may be performed substantially simultaneously, or may be performed in the opposite order from the order described.

In the following embodiments, when layers, regions, or components are connected to each other, the layers, the regions, or the components may be directly connected to each other, or another layer, another region, or another component may be interposed between the layers, the regions, or the components and thus the layers, the regions, or the components may be indirectly connected to each other. For example, in the following embodiments, when layers, regions, or components are electrically connected to each other, the layers, the regions, or the components may be directly electrically connected to each other, or another layer, another region, or another component may be interposed between the layers, the regions, or the components and thus the layers, the regions, or the components may be indirectly electrically connected to each other.

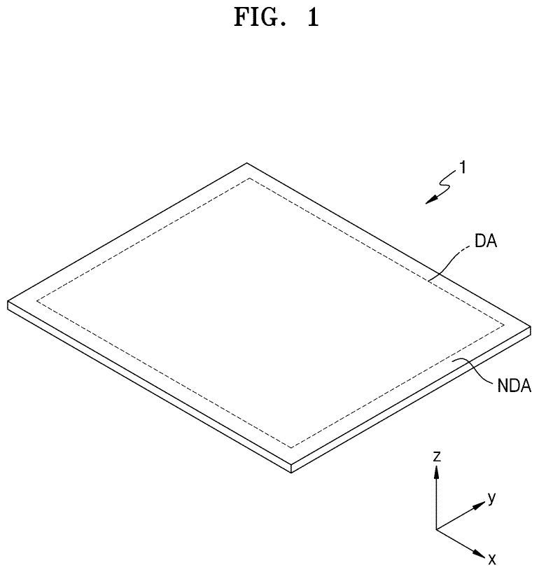

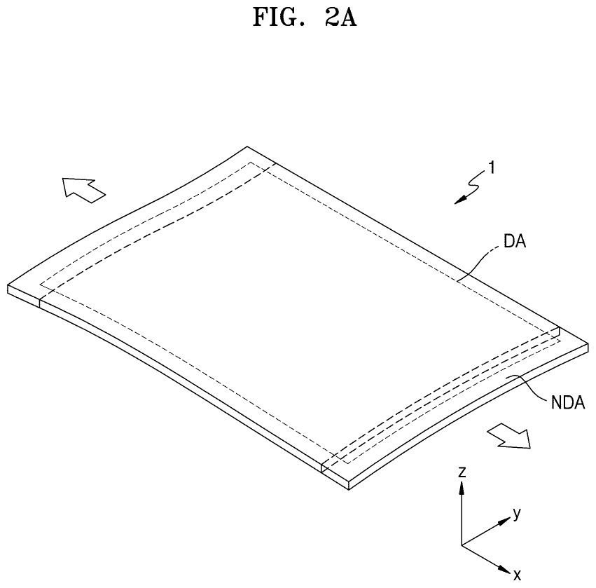

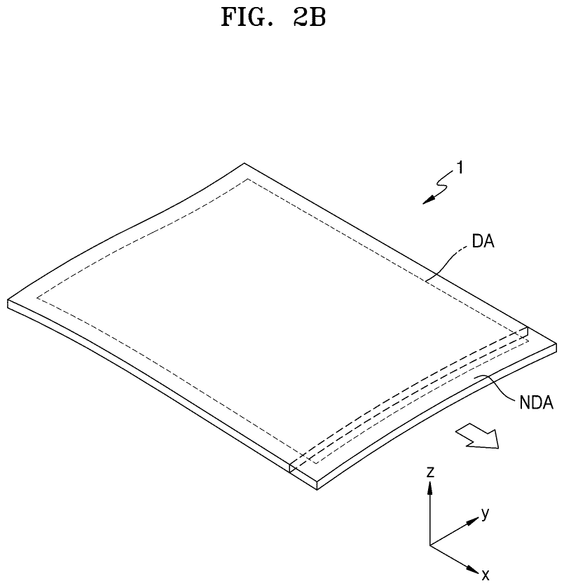

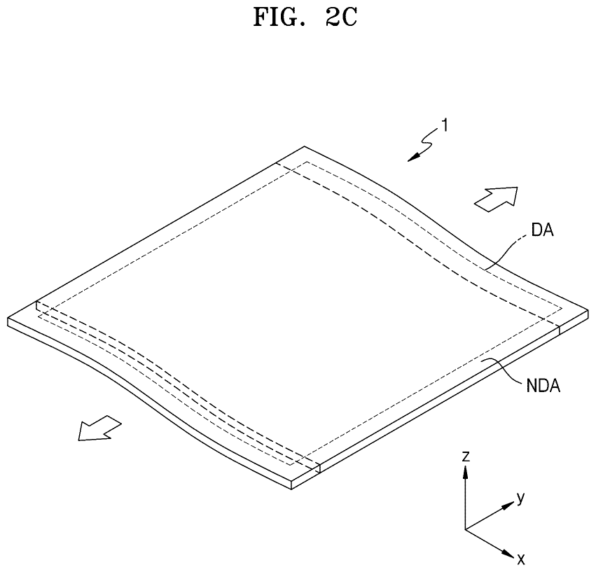

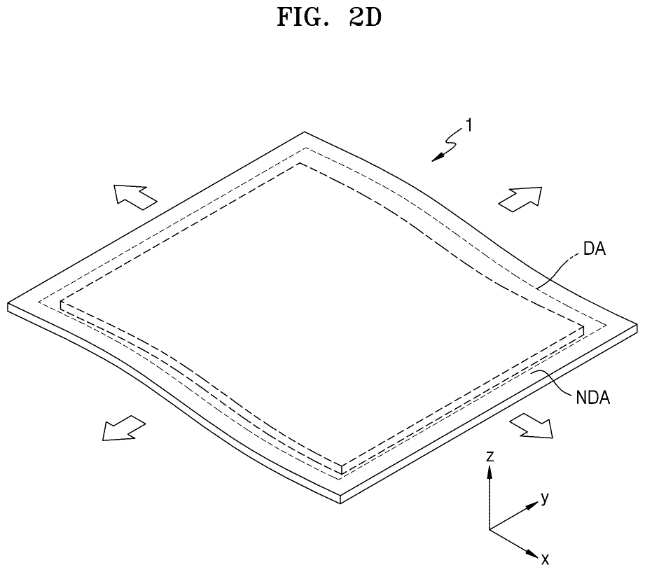

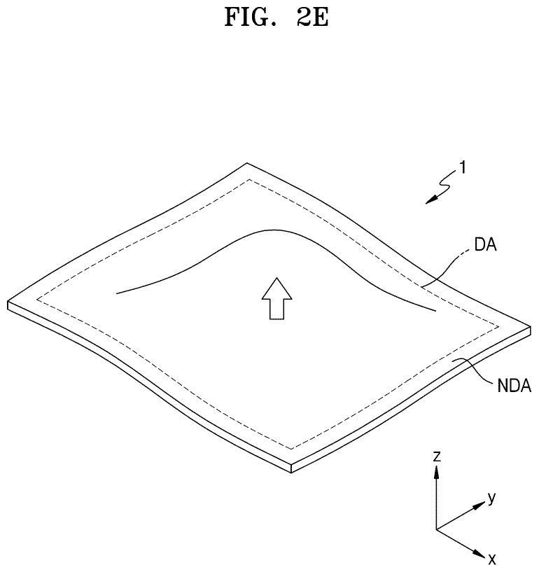

In the following embodiments, the terms x-axis, y-axis, and z-axis are not limited to, however may be interpreted in a broad sense to include, three axes in a Cartesian coordinate system. For example, the x-axis, y-axis, and z-axis may be orthogonal to each other, however may also refer to different directions that are not orthogonal to each other. FIG. 1 is a perspective view schematically showing a display device 1 according to an embodiment. FIGS. 2A and 2B are perspective views showing the display device 1 of FIG. 1 stretched in a first direction. FIG. 2C is a perspective view showing the display device 1 of FIG. 1 stretched in a second direction. FIG. 2D is a perspective view showing the display device of FIG. 1 stretched in the first and second directions. FIG. 2E is a perspective view showing the display device 1 of FIG. 1 stretched in a third direction.

Referring to FIG. 1, the display device 1 may include a display area DA and a non-display area NDA. The display area DA may include a plurality of pixels. The display device 1 may provide a certain image by light emitted from the plurality of pixels. The non-display area NDA may be placed outside the display area DA. The non-display area NDA is an area where pixels are not arranged, and may entirely surround the display area DA. The display device 1 may be stretched or shrunk in various directions. The display device 1 may be stretched in a first direction (e.g., x direction and/or −x direction) by an external force applied by an external object or a user. In an embodiment, as shown in FIGS. 2A and 2B, the display area DA and/or the non-display area NDA of the display device 1 may be stretched in the first direction (e.g., x direction and/or −x direction). For example, as shown in FIG. 2A, the display area DA and/or the non-display area NDA of the display device 1 may be stretched in the x direction and −x direction. Alternatively, as shown in FIG. 2B, the display area DA and/or the non-display area NDA of the display device 1 may be stretched in the x direction while one side of the display device 1 is fixed.

The display device 1 may be stretched in the second direction (e.g., y direction and/or −y direction) by an external force applied by an external object or a user. In an embodiment, as shown in FIG. 2C, the display area DA and/or the non-display area NDA of the display device 1 may be stretched in the y direction and −y direction. In another embodiment, the display area DA and/or the non-display area NDA of the display device 1 may be stretched in the y direction or −y direction while one side of the display device 1 is fixed.

The display device 1 may be stretched in a plurality of directions, for example, in the first direction (e.g., x direction and/or −x direction) and the second direction (e.g., y direction and/or −y direction), by an external force applied by an external object or a part of a user's body. As shown in FIG. 2D, the display area DA and/or the non-display area NDA of the display device 1 may be stretched in the ±x direction and the ±y direction.

The display device 1 may be stretched in a third direction (e.g., z direction or −z direction) by an external force applied by an external object or a part of a user's body. In an embodiment, FIG. 2E shows that a portion of the display device 1, for example, a portion of the display area DA protrudes in the z direction. In another embodiment, a portion of the display device 1, for example, a portion of the display area DA may protrude in the −z direction (or be dented in the z direction).

Although FIGS. 2A to 2E show that the display device 1 is stretched in the first direction, the second direction, and/or the third direction, the disclosure is not limited thereto. In another embodiment, the display device 1 may be transformed into various irregular shapes, such as being bent or twisted along two or more axes.

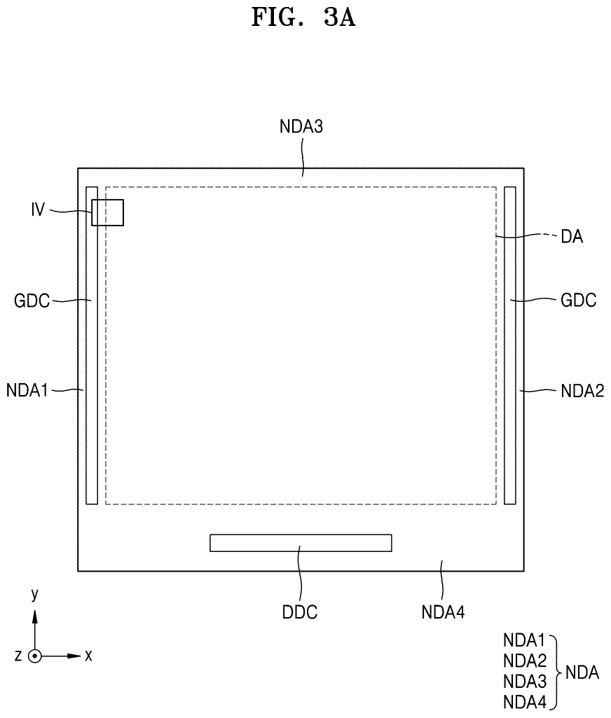

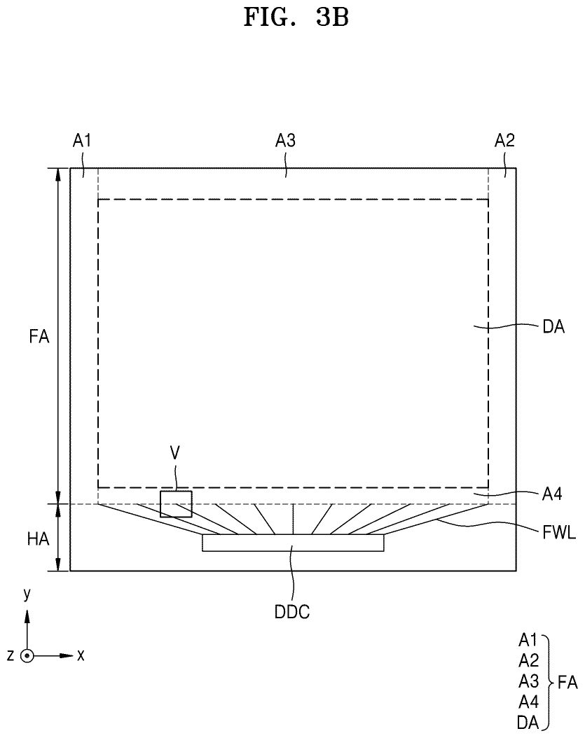

FIG. 3A is a plan view schematically showing a display device 1 according to an embodiment.

A plurality of pixels may be arranged in a display area DA of the display device 1. Each pixel may include sub-pixels that emit light of different colors. A light-emitting element corresponding to each sub-pixel may be arranged in the display area DA. A circuit for providing electrical signals to light-emitting elements arranged in the display area DA and transistors electrically connected to the light-emitting elements may be located in a non-display area NDA surrounding the display area DA. A gate driving circuit GDC may be arranged in each of a first non-display area NDA1 and a second non-display area NDA2 on both sides of the display area DA. The gate driving circuit GDC may include drivers for providing electrical signals to gate electrodes of the transistors electrically connected to the light-emitting elements. Although FIG. 3A shows that the gate driving circuit GDC is arranged in each of the first non-display area NDA1 and the second non-display area NDA2, the disclosure is not limited thereto. In another embodiment, the gate driving circuit GDC may be arranged in either the first non-display area NDA1 or the second non-display area NDA2.

A data driving circuit DDC may be arranged in a third non-display area NDA3 and/or a fourth non-display area NDA4, which connect the first non-display area NDA1 and the second non-display area NDA2 to each other. In an embodiment, FIG. 3A shows that the data driving circuit DDC is arranged in the fourth non-display area NDA4. In another embodiment, the data driving circuit DDC may be arranged in each of the third non-display area NDA3 and the fourth non-display area NDA4.

Although FIG. 3A shows that the data driving circuit DDC is arranged in the fourth non-display area NDA4 of the display device 1, the disclosure is not limited thereto. In another embodiment, the display device 1 may further include a flexible circuit board (not shown) electrically connected through a terminal portion (not shown) arranged in the fourth non-display area NDA4, and the data driving circuit DDC may be disposed on the flexible circuit board.

In some embodiments, the elongation rate of the non-display area NDA may be equal to or less than the elongation rate of the display area DA. In an embodiment, the elongation rate of the non-display area NDA may be different for each area. For example, the first non-display area NDA1, the second non-display area NDA2, and the third non-display area NDA3 may have substantially the same elongation rate, but the elongation rate of the fourth non-display area NDA4 may be less than the elongation rate of each of the first non-display area NDA1, the second non-display area NDA2, and the third non-display area NDA3.

FIG. 3B is a plan view schematically showing a display device 1 according to an embodiment.

Referring to FIG. 3B, a flexible area FA and a hard area HA may be defined in the display device 1. The flexible area FA may refer to a flexible area having a relatively high elongation rate in the display device 1, and the hard area HA may refer to a hard area having a relatively low elongation rate in the display device 1.

The flexible area FA may be an area that may be easily bent, folded, or stretched. The flexible area FA may be stretched or contracted more easily than the hard area HA. In an embodiment, a plurality of openings (not shown) may be defined in the flexible area FA. Each of the openings may pass through the display device 1. The opening may be an area where components of the display device 1 are not disposed. For example, a substrate included in the display device 1 may include an opening having the same shape as the opening in the flexible area FA. Accordingly, the display device 1 may be easily stretched and/or contracted in various directions.

The hard area HA may be a rigid area that is not easily bent. In an embodiment, the hard area HA may be an area in which an opening (not shown) passing through the display device 1 is not disposed. For example, the substrate included in the display device 1 may have an area corresponding to the hard area HA. Accordingly, the hard area HA may be an area in which stretching and/or shrinking are not easy.

The flexible area FA may include a display area DA and at least a portion of a non-display area NDA (see FIG. 3A) surrounding the display area DA. The hard area HA may include a portion of the non-display area NDA. For example, the flexible area FA may include the display area DA, the first to third non-display areas NDA1, NDA2, and NDA3, and a portion of the fourth non-display area NDA4. The hard area HA may include a portion of the fourth non-display area NDA4.

The flexible area FA may include the display area DA and a first peripheral area A1, a second peripheral area A2, a third peripheral area A3, and a fourth peripheral area A4, which surround the display area DA. For example, the first peripheral area A1 may be located on the left side (e.g., −x direction) of the display area DA, and the second peripheral area A2 may be located on the right side (e.g., x direction) of the display area DA. The third peripheral area A3 may be located on the upper side (e.g., y direction) of the display area DA and may be located between the first peripheral area A1 and the second peripheral area A2. The fourth peripheral area A4 may be located on the lower side (e.g., −y direction) of the display area DA and may be located between the first peripheral area A1 and the second peripheral area A2.

In an embodiment, the first peripheral area A1 and the second peripheral area A2 may correspond to the first non-display area NDA1 and the second non-display area NDA2 of the non-display area NDA, respectively, and a gate driving circuit GDC (see FIG. 3A) may be arranged in each of the first peripheral area A1 and the second peripheral area A2. In an embodiment, a data driving circuit DDC may be arranged in the hard area HA. In another embodiment, a flexible circuit board (not shown) electrically connected through a terminal portion (not shown) disposed in the hard area HA may be further provided, and a data driving circuit DDC may be disposed on the flexible circuit board.

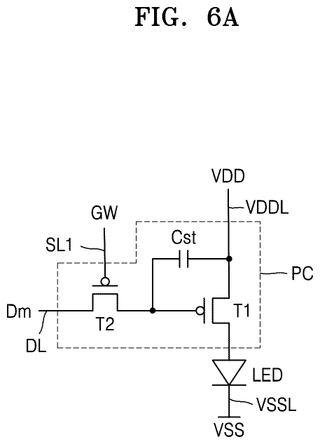

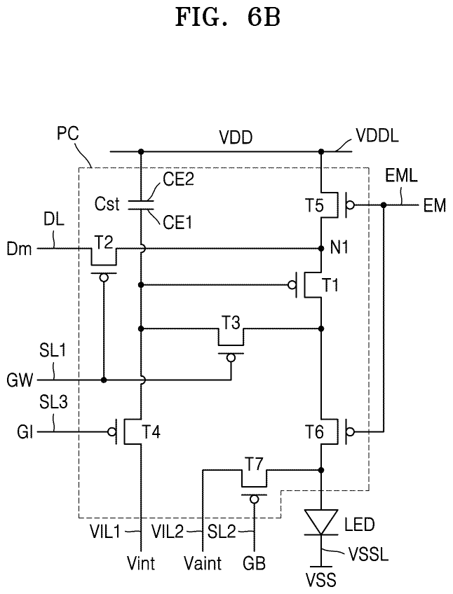

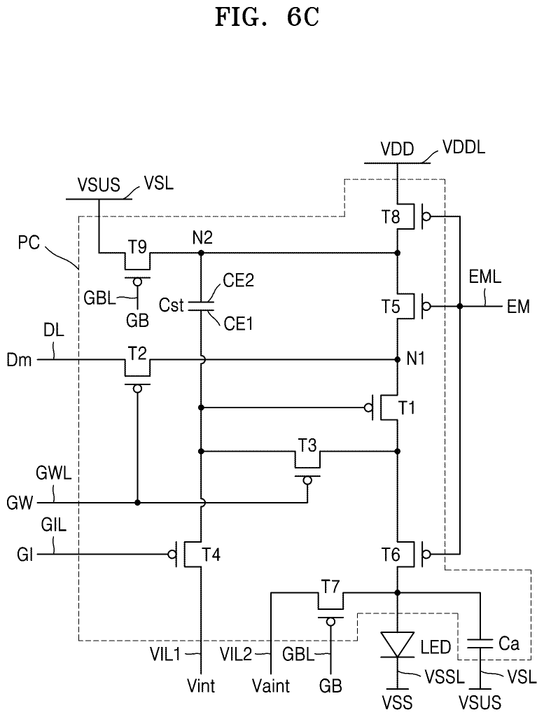

In an embodiment, a fan-out line FWL may be arranged in the hard area HA. The fan-out line FWL may extend from the data driving circuit DDC toward the display area DA. A plurality of fan-out lines FWL may be provided. In an embodiment, the fan-out line FWL may be a signal line. The fan-out line FWL may be electrically connected to a data line DL (see FIG. 6A). The length of the fan-out line FWL may vary depending on the arrangement position of the fan-out line FWL. For example, as the fan-out line FWL is arranged away from the center of the data driving circuit DDC, the fan-out line FWL may extend toward a point of the display area DA that is away from the data driving circuit DDC.

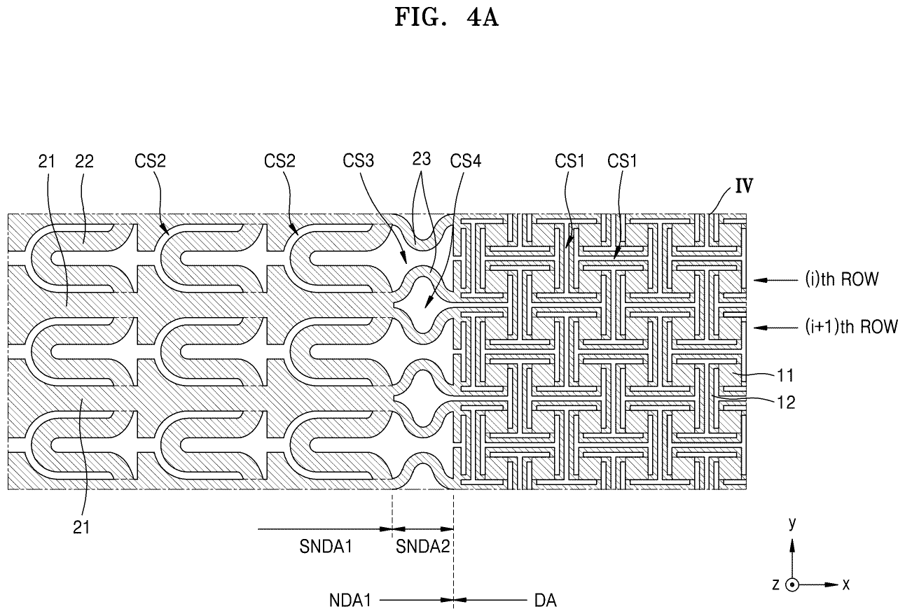

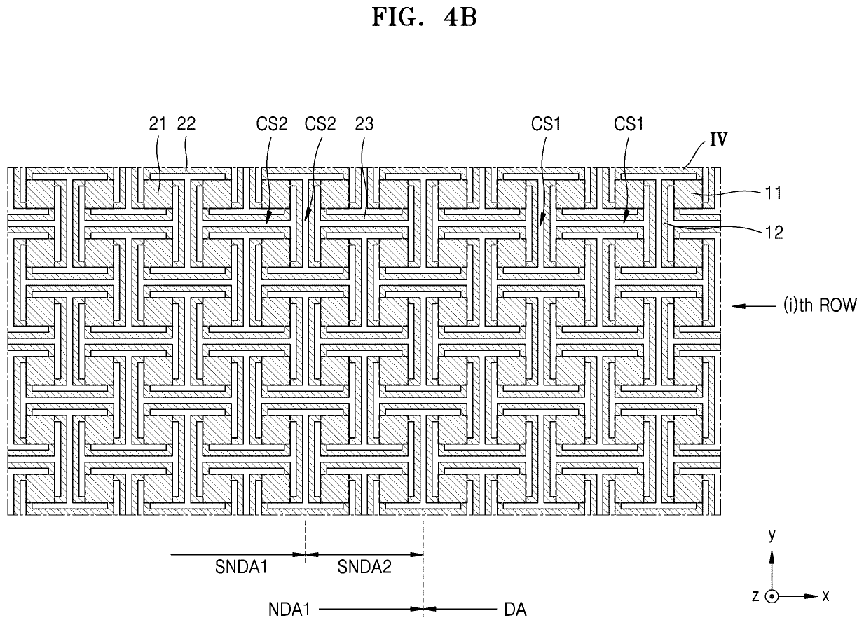

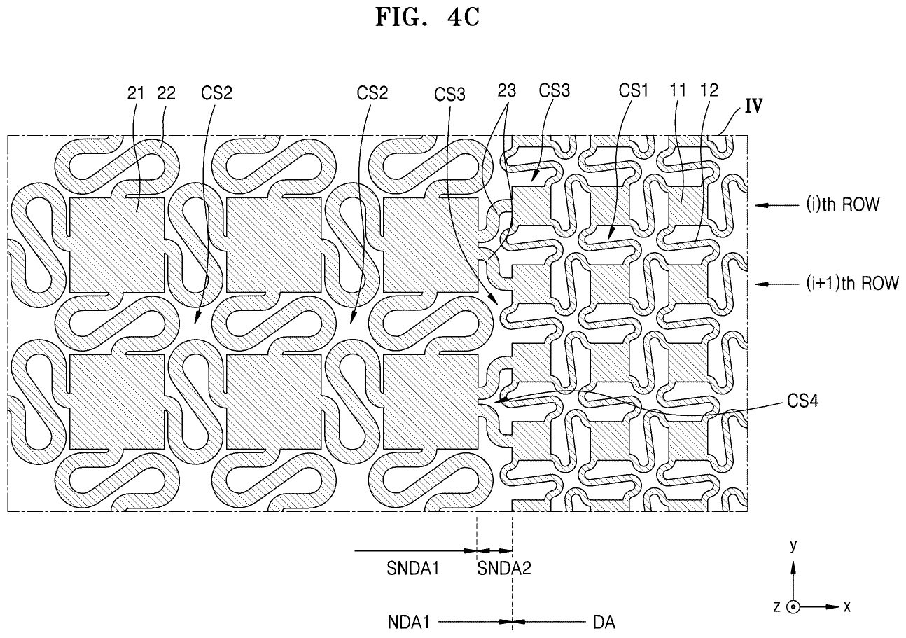

FIG. 4A is an enlarged plan view of an area IV of FIG. 3A as a portion of the display device 1 according to an embodiment.

Referring to FIG. 4A, the display device 1 may include first island portions 11 spaced apart from each other in a first direction (e.g., x direction or −x direction) and a second direction (e.g., y direction or −y direction) in the display area DA, and first bridge portions 12 connecting adjacent first island portions 11 to each other.

Each of the first island portions 11 may be connected to a plurality of first bridge portions 12. For example, each of the first island portions 11 may be connected to four first bridge portions 12. Two first bridge portions 12 may be disposed on both sides of the first island portion 11 in the first direction (e.g., x direction or −x direction), and the other two first bridge portions 12 may be disposed on both sides of the first island portion 11 in the second direction (e.g., y direction or −y direction). In an embodiment, the four first bridge portions 12 may be respectively connected to the four sides of the first island portion 11. Each of the four first bridge portions 12 may be adjacent to a corner of the first island portion 11.

The first bridge portions 12 may be spaced apart from each other by a first opening CS1 located between the first bridge portions 12. In an embodiment, a first opening CS1 approximately having an H shape and a first opening CS1 approximately having an I shape obtained by rotating the H shape by 90 degrees may be alternately and repeatedly arranged in the first direction (e.g., x direction or −x direction) and the second direction (e.g., y direction or −y direction). Both ends of each first bridge portion 12 may be connected to each of the adjacent first island portions 11, and one side of each first bridge portion 12 may be spaced apart from one side of an adjacent first island portion 11 and/or one side of another first bridge portion 12 by the first opening CS1.

The display device 1 may include second island portions 21 spaced apart from each other in a non-display area, for example, the first non-display area NDA1 shown in FIG. 4A, and second bridge portions 22 connecting adjacent second island portions 21 to each other.

Each of the second island portions 21 may extend in the first direction (e.g., x direction or −x direction). The second island portions 21 may be spaced apart from each other in the second direction (e.g., y direction or −y direction) that crosses the first direction (e.g., x direction or −x direction). Each second island portion 21 may include drivers of the gate driving circuit GDC (see FIG. 3A) described with reference to FIG. 3A.

The second bridge portion 22 may have a serpentine shape. The length of the second bridge portion 22 may be greater than the shortest distance between adjacent second island portions 21 in the second direction (e.g., y direction or −y direction). In an embodiment, the second bridge portion 22 may approximately have an omega (Ω) shape that is convex toward the first direction (e.g., x direction or −x direction). The second bridge portions 22 may be arranged between adjacent second island portions 21 and may be spaced apart from each other.

The second bridge portions 22 between adjacent second island portions 21 may be spaced apart from each other by second openings CS2. Between the adjacent second island portions 21, the second openings CS2 and the second bridge portions 22 may be alternately arranged in the first direction (e.g., x direction or −x direction). The second openings CS2 may have the same shape. Both ends of each second bridge portion 22 may be connected to each of the adjacent second island portions 21, and one side of each second bridge portion 22 may be spaced apart from one side of an adjacent second island portion 21 and/or one side of another second bridge portion 22 by the second opening CS2.

One of the second island portions 21 arranged in the first non-display area NDA1 may correspond to a plurality of rows of first island portions 11 arranged in the display area DA1. For example, one of the second island portions 21 arranged in the first non-display area NDA1 may correspond to first island portions 11 arranged in the (i)th row and first island portions 11 arranged in the (i+1)th row in the display area DA (where i is a positive number greater than 0). Although FIG. 4A shows that one second island portion 21 corresponds to two rows of first island portions 11, the disclosure is not limited thereto. In another embodiment, one second island portion 21 arranged in the first non-display area NDA1 may correspond to n rows of first island portions 11 arranged in the display area DA1 (where n is a positive number that is equal to or greater than 3).

The non-display area, for example, the first non-display area NDA1, may include a first sub-non-display area SNDA1 in which the second island portions 21 and the second bridge portions 22, described above are arranged, and a second sub-non-display area SNDA2 between the first sub-non-display area SNDA1 and the display area DA. Third bridge portions 23 may be arranged in the second sub-non-display area SNDA2 to connect the display area DA with the first sub-non-display area SNDA1. One end of the third bridge portion 23 may be connected to the second island portion 21 and/or the second bridge portion 22, and the other end of the third bridge portion 23 may be connected to the first island portion 11 and/or the first bridge portion 12.

The third bridge portion 23 may have a serpentine shape. In an embodiment, the shape of the third bridge portion 23 may be different from the shape of each of the first bridge portion 12 and the second bridge portion 22. In an embodiment, as shown in FIG. 4A, the third bridge portion 23 may approximately have an Ω shape that is convex toward the second direction (e.g., y direction or −y direction). The third bridge portions 23 may have a symmetrical structure, in which one of the adjacent third bridge portions 23 arranged in the second direction (e.g., y direction or −y direction) is convex in the y direction and the other is convex in the −y direction. Between the third bridge portions 23, third openings CS3 and fourth openings CS4 of different shapes may have a repeated structure. The width of the third bridge portion 23 may be different from the width of the first bridge portion 12 and the width of the second bridge portion 22. In an embodiment, the width of the third bridge portion 23 may be greater than the width of the first bridge portion 12 and may be less than the width of the second bridge portion 22.

FIG. 4A shows that the second island portion 21 and the second bridge portion 22 in the non-display area, for example, the first non-display area NDA1, have different shapes from the first island portion 11 and the first bridge portion 12, respectively, in the display area DA. In another embodiment of the disclosure, the second island portion 21 and the second bridge portion 22 in the non-display area may have the same shape as the first island portion 11 and the first bridge portion 12, respectively, in the display area DA.

FIG. 4B is an enlarged plan view of an area IV of FIG. 3A as a portion of the display device 1 according to another embodiment.

Referring to FIG. 4B, the display device 1 may include first island portions 11 spaced apart from each other in a display area DA and first bridge portions 12 spaced apart from each other by a first opening CS1 and connecting adjacent first island portions 11 to each other. The structure of the display area DA in FIG. 4B may be the same as the structure of the display area DA previously described with reference to FIG. 4A.

The display device 1 may include second island portions 21 and second bridge portions 22, arranged in a non-display area, for example, a first non-display area NDA1. In an embodiment, the second island portions 21 and the second bridge portions 22 may have substantially the same shape as the first island portions 11 and the first bridge portions 12, respectively.

The second island portions 21 may be spaced apart from each other in a first direction (e.g., x direction or −x direction) and a second direction (e.g., y direction or −y direction) in the non-display area, for example, the first non-display area NDA1. Each of the second bridge portions 22 may connect adjacent second island portions 21 to each other. The second bridge portions 22 may be spaced apart from each other by a second opening CS2 located between the second bridge portions 22.

The second opening CS2 may have substantially the same shape as the first opening CS1. For example, a second opening CS2 approximately having an H shape and a second opening CS2 approximately having an I shape may be alternately and repeatedly arranged in the non-display area, for example, the first non-display area NDA1. Both ends of each second bridge portion 22 may be connected to each of the adjacent second island portions 21, and one side of each second bridge portion 22 may be spaced apart from one side of an adjacent second island portion 21 and/or one side of another second bridge portion 22 by the second opening CS2.

Each second island portion 21 may be connected to four second bridge portions 22. Each second island portion 21 may include drivers of the gate driving circuit GDC (see FIG. 3A) described with reference to FIG. 3A.

Second island portions 21 in one row arranged in the first non-display area NDA1 may correspond to first island portions 11 in one row arranged in the display area DA1. For example, second island portions 21 arranged in the (i) th row in the first direction (e.g., x direction or −x direction) in the first non-display area NDA1 may correspond to first island portions 11 arranged in the same row, for example, the (i)th row, in the display area DA (where i is a positive number greater than 0).

The display device 1 may include third bridge portions 23 arranged in the second sub-non-display area SNDA2 for connecting the display area DA to the first sub-non-display area SNDA1. A non-display area, for example, the first non-display area NDA1, may include a first sub-non-display area SNDA1 in which the second island portions 21 and the second bridge portions 22 are arranged, and a second sub-non-display area SNDA2 including third bridge portions 23 and located between the first sub-non-display area SNDA1 and the display area DA. The third bridge portion 23 may be substantially the same as the first bridge portion 12 and the second bridge portion 22. For example, the width of the third bridge portion 23 may be the same as the width of the first bridge portion 12 and the width of the second bridge portion 22.

FIG. 4C is an enlarged plan view of an area IV of FIG. 3A as a portion of a display device according to still another embodiment.

Referring to FIG. 4C, the display device 1 may include first island portions 11 spaced apart from each other in a first direction (e.g., x direction or −x direction) and a second direction (e.g., y direction or −y direction) in the display area DA, and first bridge portions 12 connecting adjacent first island portions 11 to each other.

The first bridge portions 12 may be arranged to be spaced apart from each other by the first opening CS1 located between the first bridge portions 12. The first bridge portion 12 may have a serpentine shape. For example, as shown in FIG. 4C, the first bridge portion 12 may approximately have a shape of ‘the letter S’.

Each of the first island portions 11 may be connected to a plurality of first bridge portions 12. For example, each of the first island portions 11 may be connected to four first bridge portions 12. Two first bridge portions 12 may be disposed on both sides of the first island portion 11 in the first direction (e.g., x direction or −x direction), and the other two first bridge portions 12 may be disposed on both sides of the first island portion 11 in the second direction (e.g., y direction or −y direction). The four first bridge portions 12 may be respectively connected to the four sides of the first island portion 11. Each of the four first bridge portions 12 may be adjacent to a corner of the first island portion 11.

The display device 1 may include second island portions 21 spaced apart from each other in a first direction (e.g., x direction or −x direction) and a second direction (e.g., y direction or −y direction) in a non-display area, for example, in the first non-display area NDA1 shown in FIG. 4C, and second bridge portions 22 connecting adjacent second island portions 21 to each other.

The second bridge portions 22 may be arranged to be spaced apart from each other by the second opening CS2 located between the second bridge portions 22. The second bridge portion 22 may have a serpentine shape. For example, as shown in FIG. 4C, the second bridge portion 22 may approximately have a shape of ‘the letter S’. The size and/or width of the second bridge portion 22 may be different from the size and/or width of the first bridge portion 12. For example, the size and/or width of the second bridge portion 22 may be greater than the size and/or width of the first bridge portion 12. The radius of curvature of a round portion of the second bridge portion 22 may be different from the radius of curvature of a round portion of the first bridge portion 12. For example, the radius of curvature of the round portion of the second bridge portion 22 may be greater than the radius of curvature of the round portion of the first bridge portion 12.

Each of the second island portions 21 may be connected to a plurality of second bridge portions 22. Each of the second island portions 21 may be connected to four second bridge portions 22. Two second bridge portions 22 may be disposed on both sides of the second island portion 21 in the first direction (e.g., x direction or −x direction), and the other two second bridge portions 22 may be disposed on both sides of the second island portion 21 in the second direction (e.g., y direction or −y direction). In an embodiment, the four second bridge portions 22 may be respectively connected to the four sides of the second island portion 21. Each second bridge portion 22 may be connected to a central portion of each side of the second island portion 21.

Second island portions 21 in one row arranged in the first non-display area NDA1 may correspond to first island portions 11 in a plurality of rows arranged in the display area DA1. For example, the second island portions 21 in one row arranged in the first non-display area NDA1 may correspond to first island portions 11 arranged in the (i)th row of the display area DA and first island portions 11 arranged in the (i+1)th row (where i is a positive number greater than 0). In another embodiment, one row of second island portions 21 may correspond to n rows of first island portions 11 (where n is a positive number that is equal to or greater than 3).

The non-display area, for example, the first non-display area NDA1, may include a first sub-non-display area SNDA1 in which the second island portions 21 and the second bridge portions 22, described above, are arranged, and a second sub-non-display area SNDA2 between the first sub-non-display area SNDA1 and the display area DA. Third bridge portions 23 may be arranged in the second sub-non-display area SNDA2 to connect the display area DA with the first sub-non-display area SNDA1. One end of the third bridge portion 23 may be connected to the second island portion 21 and the other end of the third bridge portion 23 may be connected to the first island portion 11. For example, one end of the third bridge portion 23 may be connected to a central portion of one side of the second island portion 21, and the other end of the third bridge portion 23 may be connected to a central portion of one side of the first island portion 11.

The third bridge portion 23 may have a serpentine shape. In an embodiment, the shape of the third bridge portion 23 may be different from the shape of each of the first bridge portion 12 and the second bridge portion 22. The width of the third bridge portion 23 may be different from the width of the first bridge portion 12 and the width of the second bridge portion 22. The width of the third bridge portion 23 may be greater than the width of the first bridge portion 12 and may be less than the width of the second bridge portion 22. Third openings CS3 and fourth openings CS4 of different shapes may be alternately arranged between the third bridge portions 23 in the second direction (e.g., y direction or −y direction).

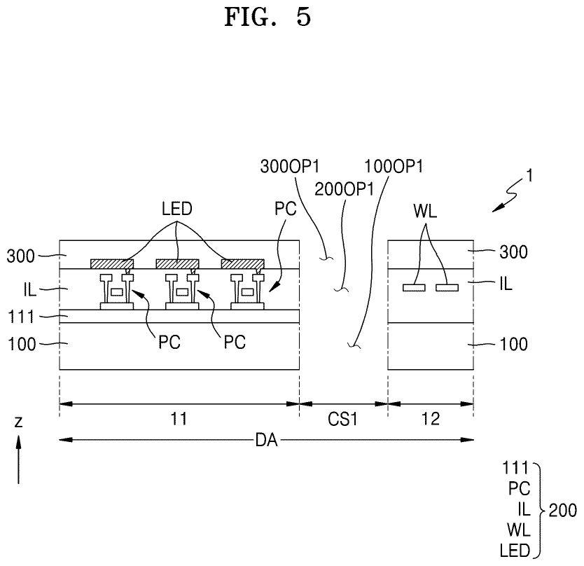

FIG. 5 is a cross-sectional view schematically showing a first island portion 11 and a first bridge portion 12 disposed in a display area DA of a display device 1 according to an embodiment.

Referring to FIG. 5, the first island portion 11 and the first bridge portion 12 disposed in the display area DA may be spaced apart from each other with a first opening CS1 therebetween. The first island portion 11 may include light-emitting elements LED and a circuit (e.g., pixel driving circuit portion PC) for driving the light-emitting elements LED electrically connected thereto, and the first bridge portion 12 may include a wiring line WL electrically connected to pixel driving circuit portions PC arranged in each of the adjacent first island portions 11.

In the first island portion 11, a buffer layer 111 including an inorganic insulating material may be disposed on a substrate 100, and a pixel driving circuit portion PC may be disposed on the buffer layer 111. An insulating layer IL including an inorganic insulating material and/or an organic insulating material may be disposed between the pixel driving circuit portion PC and the light-emitting element LED. The light-emitting element LED may be disposed on the insulating layer IL and may be electrically connected to a corresponding pixel driving circuit portion PC. Light-emitting elements LED may emit light of different colors or the same color. In an embodiment, each of the light-emitting elements LED may emit red light, green light, or blue light. In some embodiments, the light-emitting elements LED may emit white light. In another embodiment, each of the light-emitting elements LED may emit red light, green light, blue light, or white light.

The substrate 100 may include a polymer resin, such as polyethersulfone, polyarylate, polyether imide, polyethylene naphthalate, polyethylene terephthalate, polyphenylene sulfide, polyimide, polycarbonate, cellulose triacetate, or cellulose acetate propionate. In an embodiment, the substrate 100 may include a single layer including the aforementioned resin. In another embodiment, the substrate 100 may have a multi-layered structure including a base layer including the aforementioned polymer resin and a barrier layer including an inorganic insulating material. The substrate 100 including a polymer resin may be flexible, rollable, or bendable.

In an embodiment, FIG. 5 shows that three pixel driving circuit portions PC are arranged in each of the first island portions 11 and three light-emitting elements LED are respectively connected to the pixel driving circuit portions PC. However, the disclosure is not limited thereto. In another embodiment, the number of pixel driving circuit portions PC and light-emitting elements LED arranged in the first island portion 11 may be one, two, or four or more.

An encapsulation layer 300 may be disposed on the light-emitting elements LED and may protect the light-emitting elements LED from external force and/or moisture penetration. The encapsulation layer 300 may include an inorganic encapsulation layer and/or an organic encapsulation layer. In some embodiments, the encapsulation layer 300 may have a structure in which an inorganic encapsulation layer including an inorganic insulating material, an organic encapsulation layer including an organic insulating material, and an inorganic encapsulation layer including an inorganic insulating material are stacked. In another embodiment, the encapsulation layer 300 may include an organic material, such as resin. In some embodiments, the encapsulation layer 300 may include urethane epoxy acrylate. The encapsulation layer 300 may include a photosensitive material, such as photoresist.

In the first bridge portion 12, an insulating layer IL including an organic insulating material may be disposed on the substrate 100. When the display device 1 is stretched, unlike the first island portion 11, there may not be a layer including an inorganic insulating material, which is prone to cracks, in the first bridge portion 12, which is relatively transformed. In an embodiment, the substrate 100 corresponding to the first bridge portion 12 may have the same stacked structure as the substrate 100 corresponding to the first island portion 11. In an embodiment, the substrate 100 corresponding to the first bridge portion 12 and the substrate 100 corresponding to the first island portion 11 may be polymer resin layers formed together in the same process. In another embodiment, the substrate 100 corresponding to the first bridge portion 12 may have a different stack structure from the substrate 100 corresponding to the first island portion 11. In some embodiments, the substrate 100 corresponding to the first island portion 11 may have a multi-layered structure including a base layer including a polymer resin and a barrier layer including an inorganic insulating material, and the substrate 100 corresponding to the first bridge portion 12 may have a structure of a polymer resin layer without a layer including an inorganic insulating material.

As described above, wiring lines WL of the first bridge portion 12 may be signal lines (e.g., gate lines and data lines) for providing electrical signals to transistors included in the pixel driving circuit portion PC of the first island portion 11, or voltage lines (e.g., driving voltage lines and initialization voltage lines) for providing voltages. The encapsulation layer 300 may also be arranged in the first bridge portion 12. In another embodiment, the encapsulation layer 300 may not be present in the first bridge portion 12.

Referring to FIGS. 4A to 4C and FIG. 5, the substrate 100 corresponding to the first island portion 11 and the substrate 100 corresponding to the first bridge portion 12 may be connected to each other. In other words, the plan views shown in FIGS. 4A to 4C may be substantially the same as the plan view of the substrate 100 in FIG. 5. In other words, the substrate 100 may include an area corresponding to the first island portion 11, an area corresponding to the first bridge portion 12, and an opening 100OP1 having the same shape as the first opening CS1.

Similarly, the encapsulation layer 300 corresponding to the first island portion 11 and the encapsulation layer 300 corresponding to the first bridge portion 12 may be connected to each other. For example, the plan views shown in FIGS. 4A to 4C may be substantially the same as the plan view of the encapsulation layer 300. In other words, the encapsulation layer 300 may include an area corresponding to the first island portion 11, an area corresponding to the first bridge portion 12, and an opening 300OP1 having the same shape as the first opening CS1.

A circuit-light-emitting element layer 200 between the substrate 100 and the encapsulation layer 300 may include a buffer layer 111, a pixel driving circuit portion PC, a wiring line WL, an insulating layer IL, and a light-emitting element LED. Similar to the substrate 100, the plan view shown in FIGS. 4A to 4C may be substantially the same as the plan view of the circuit-light-emitting element layer 200. In other words, the circuit-light-emitting element layer 200 may include an opening 200OP1 having the same shape as the first opening CS1.

FIGS. 6A to 6C are equivalent circuit diagrams of a sub-pixel of the display device 1 according to an embodiment.

Referring to FIG. 6A, a light-emitting element LED corresponding to the sub-pixel may be electrically connected to a pixel driving circuit PC, and the pixel driving circuit PC may include a first transistor T1, a second transistor T2, and a storage capacitor Cst. The pixel driving circuit portion PC may be electrically connected to a signal line and a voltage line. The signal line may include a gate line such as a first scan line SL1, and a data line DL, and the voltage line may include a first voltage line VDDL.

The second transistor T2 may be electrically connected to the first scan line SL1 and the data line DL. The first scan line SL1 may provide a first scan signal GW to a gate electrode of the second transistor T2. The second transistor T2 may be configured to transmit a data signal Dm input from the data line DL to the first transistor T1 according to the first scan signal GW input from the first scan line SL1.

The storage capacitor Cst may be electrically connected to the second transistor T2 and the first voltage line VDDL and may store a voltage corresponding to the difference between a voltage received from the second transistor T2 and a first power voltage VDD supplied by the first voltage line VDDL.

The first transistor T1 may be a driving transistor and may be configured to control a driving current flowing through the light-emitting element LED. The first transistor T1 may be connected to the first voltage line VDDL and the storage capacitor Cst. The first transistor T1 may be configured to control a driving current flowing from the first voltage line VDDL to the light-emitting element LED, in response to a voltage value stored in the storage capacitor Cst. The light-emitting element LED may emit light having a certain brightness by the driving current. A first electrode of the light-emitting element LED may be electrically connected to the first transistor T1, and a second electrode of the light-emitting element LED may be electrically connected to a second voltage line VSSL configured to supply a second power voltage VSS.

FIG. 6A shows that the pixel driving circuit portion PC includes two transistors and one storage capacitor. However, in another embodiment, the pixel driving circuit portion PC may include three or more transistors.

Referring to FIG. 6B, a pixel driving circuit portion PC may include a first transistor T1, a second transistor T2, a third transistor T3, a fourth transistor T4, a fifth transistor T5, a sixth transistor T6, a seventh transistor T7, and a storage capacitor Cst.

The pixel driving circuit portion PC is electrically connected to signal lines and voltage lines. The signal lines may include gate lines, such as a first scan line SL1, a second scan line SL2, a third scan line SL3, and an emission control line EML, and a data line DL. The voltage lines may include first and second initialization voltage lines VIL1 and VIL2 and a first voltage line VDDL.

The first voltage line VDDL may be configured to transmit a first power voltage VDD to the first transistor T1. The first initialization voltage line VIL1 may be configured to transmit a first initialization voltage Vint, which initializes the first transistor T1, to the pixel driving circuit portion PC. The second initialization voltage line VIL2 may be configured to transmit a second initialization voltage Vaint, which initializes a first electrode of a light-emitting element LED, to the pixel driving circuit portion PC.

The first transistor T1 may be electrically connected to the first voltage line VDDL via the fifth transistor T5 and may be electrically connected to the light-emitting element LED via the sixth transistor T6. The first transistor T1 may function as a driving transistor and may be configured to receive a data signal Dm according to a switching operation of the second transistor T2 and supply a driving current to the light-emitting element LED.

The second transistor T2 may be a data writing transistor and may be electrically connected to the first scan line SL1 and the data line DL. The second transistor T2 may be electrically connected to the first voltage line VDDL via the fifth transistor T5. The second transistor T2 may be configured to be turned on according to a first scan signal GW received through the first scan line SL1 and transmit the data signal Dm transmitted to the data line DL to a first node N1. That is, the second transistor T2 may be configured to perform a switching operation.

The third transistor T3 may be electrically connected to the first scan line SL1 and to the light-emitting element LED via the sixth transistor T6. The third transistor T3 may be configured to be turned on according to a first scan signal GW received through the first scan line SL1 and diode-connect the first transistor T1.

The fourth transistor T4 may be a first initialization transistor and may be electrically connected to the third scan line SL3 and the first initialization voltage line VIL1. The fourth transistor T4 may be configured to be turned on according to a third scan signal GI received through the third scan line SL3 and transmit the first initialization voltage Vint from the first initialization voltage line VIL1 to a gate electrode of the first transistor T1 to initialize the voltage of the gate electrode of the first transistor T1. The third scan signal GI may correspond to the first scan signal of another pixel driving circuit portion arranged in the previous row of a corresponding pixel driving circuit portion PC.

The fifth transistor T5 may be an operation control transistor, and the sixth transistor T6 may be an emission control transistor. The fifth transistor T5 and the sixth transistor T6 may be electrically connected to the emission control line EML and may be configured to be simultaneously turned on according to an emission control signal EM received through the emission control line EML and form a current path so that a driving current may flow from the first voltage line VDDL to the light-emitting element LED.

The seventh transistor T7 may be a second initialization transistor and may be electrically connected to the second scan line SL2, the second initialization voltage line VIL2, and the sixth transistor T6. The seventh transistor T7 may be configured to be turned on according to a second scan signal GB received through the second scan line SL2 and transmit the second initialization voltage Vaint from the second initialization voltage line VIL2 to the first electrode of the light-emitting element LED to initialize the first electrode of the light-emitting element LED.

The storage capacitor Cst may include a first electrode CE1 and a second electrode CE2. The first electrode CE1 may be electrically connected to the gate electrode of the first transistor T1, and the second electrode CE2 may be electrically connected to the first voltage line VDDL. The storage capacitor Cst may store and maintain a voltage corresponding to the voltage difference between the first voltage line VDDL and the gate electrode of the first transistor T1, thereby maintain the voltage applied to the gate electrode of the first transistor T1.

Referring to FIG. 6C, a pixel driving circuit portion PC may include a first transistor T1, a second transistor T2, a third transistor T3, a fourth transistor T4, a fifth transistor T5, a sixth transistor T6, a seventh transistor T7, an eighth transistor T8, a ninth transistor T9, a storage capacitor Cst, and an auxiliary capacitor Ca.

The pixel driving circuit portion PC may be electrically connected to signal lines and voltage lines. The signal lines may include gate lines, such as a first scan line SL1, a second scan line SL2, a third scan line SL3, and an emission control line EML, and a data line DL. The voltage lines may include first and second initialization voltage lines VIL1 and VIL2, a maintenance voltage line VSL, and a first voltage line VDDL.

The first voltage line VDDL may be configured to transmit a first power voltage VDD to the first transistor T1. The first initialization voltage line VIL1 may be configured to transmit a first initialization voltage Vint, which initializes the first transistor T1, to the pixel driving circuit portion PC. The second initialization voltage line VIL2 may be configured to transmit a second initialization voltage Vaint, which initializes a first electrode of a light-emitting element LED, to the pixel driving circuit portion PC. The maintenance voltage line VSL may be configured to provide a maintenance voltage VSUS to a second node N2, for example, a second electrode CE2 of the storage capacitor Cst, during an initialization period and a data writing period.

The first transistor T1 may be electrically connected to the first voltage line VDDL via the fifth transistor T5 and the eighth transistor T8 and may be electrically connected to the light-emitting element LED via the sixth transistor T6. The first transistor T1 may function as a driving transistor and may be configured to receive a data signal Dm according to a switching operation of the second transistor T2 and supply a driving current to the light-emitting element LED.

The second transistor T2 may be electrically connected to the first scan line SL1 and the data line DL and may be electrically connected to the first voltage line VDDL via the fifth transistor T5 and the eighth transistor T8. The second transistor T2 may be configured to be turned on according to a first scan signal GW received through the first scan line SL1 and transmit the data signal Dm transmitted to the data line DL to a first node N1. That is, the second transistor T2 may be configured to perform a switching operation.

The third transistor T3 may be electrically connected to the first scan line SL1 and to the light-emitting element LED via the sixth transistor T6. The third transistor T3 may be configured to be turned on according to a first scan signal GW received through the first scan line SL1 and diode-connect the first transistor T1, thereby compensating for the threshold voltage of the first transistor T1.

The fourth transistor T4 may be electrically connected to the third scan line SL3 and the first initialization voltage line VIL1 and may be configured to be turned on according to a third scan signal GI received through the third scan line SL3 and transmit the first initialization voltage Vint from the first initialization voltage line VIL1 to a gate electrode of the first transistor T1 to initialize the voltage of the gate electrode of the first transistor T1. The third scan signal GI may correspond to the first scan signal of another pixel driving circuit portion arranged in the previous row of a corresponding pixel driving circuit portion PC.

The fifth transistor T5, the sixth transistor T6, and the eighth transistor T8 may be electrically connected to the emission control line EML and may be configured to be simultaneously turned on according to an emission control signal EM received through the emission control line EML and form a current path so that a driving current may flow from the first voltage line VDDL to the light-emitting element LED.

The seventh transistor T7 may be a second initialization transistor and may be electrically connected to the second scan line SL2, the second initialization voltage line VIL2, and the sixth transistor T6. The seventh transistor T7 may be configured to be turned on according to a second scan signal GB received through the second scan line SL2 and transmit the second initialization voltage Vaint from the second initialization voltage line VIL2 to the first electrode of the light-emitting element LED to initialize the first electrode of the light-emitting element LED.

The ninth transistor T9 may be electrically connected to the second scan line SL2, the second electrode CE2 of the storage capacitor Cst, and the maintenance voltage line VSL. The ninth transistor T9 may be configured to be turned on according to a second scan signal GB received through the second scan line SL2 and transmit a maintenance voltage VSUS to a second node N2, for example, the second electrode CE2 of the storage capacitor Cst, during an initialization period and a data writing period.

The eighth transistor T8 and the ninth transistor T9 may each be electrically connected to the second node N2, for example, the second electrode CE2 of the storage capacitor Cst. In some embodiments, in the initialization period and the data writing period, the eighth transistor T8 may be turned off and the ninth transistor T9 may be turned on, and in an emission period, the eighth transistor T8 may be turned on and the ninth transistor T9 may be turned off. Because the maintenance voltage VSUS is transmitted to the second node N2 in the initialization period and the data writing period, the uniformity (e.g., long range uniformity (“LRU”)) of luminance of the display device according to the voltage drop of the first voltage line VDDL may be improved.

The storage capacitor Cst may include a first electrode CE1 and a second electrode CE2. The first electrode CE1 may be electrically connected to the gate electrode of the first transistor T1, and the second electrode CE2 may be electrically connected to the eighth transistor T8 and the ninth transistor T9.

The auxiliary capacitor Ca may be electrically connected to the sixth transistor T6, the maintenance voltage line VSL, and the first electrode of the light-emitting element LED. The auxiliary capacitor Ca may store and maintain a voltage corresponding to the voltage difference between the first electrode of the light-emitting element LED and the maintenance voltage line VSL while the seventh transistor T7 and the ninth transistor T9 are turned on, and thus may prevent black luminance from increasing when the sixth transistor T6 is turned off.

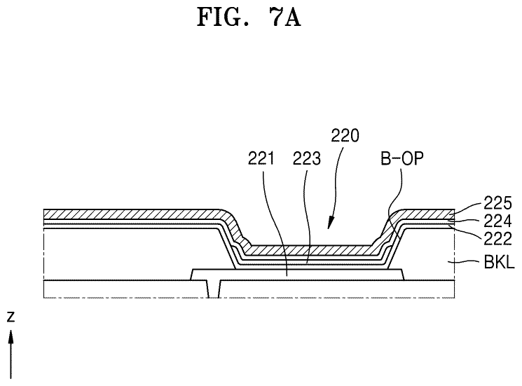

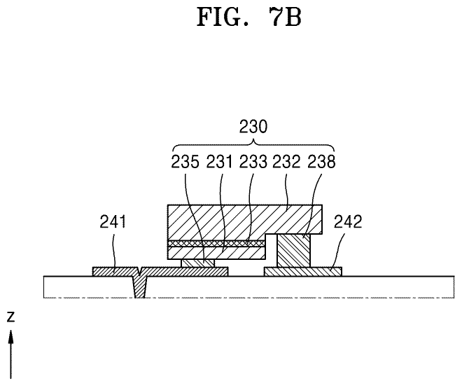

FIG. 7A is a cross-sectional view schematically showing a light-emitting element of a display device according to an embodiment.

Referring to FIG. 7A, a light-emitting element according to an embodiment may include an organic light-emitting diode 220 including an organic material. The organic light-emitting diode 220 may include a first electrode 221 disposed on an insulating layer, a second electrode 225 facing the first electrode 221, and an emission layer 223 disposed between the first electrode 221 and the second electrode 225. A first functional layer 222 may be disposed between the first electrode 221 and the emission layer 223, and a second functional layer 224 may be disposed between the emission layer 223 and the second electrode 225.

The edge of the first electrode 221 may be covered with a bank layer BKL including an insulating material. The bank layer BKL may include an opening B-OP overlapping a center portion of the first electrode 221.

The first electrode 221 may include a conductive oxide, such as indium tin oxide (“ITO”), indium zinc oxide (“IZO”), zinc oxide (ZnO), indium oxide (In₂O₃), indium gallium oxide (“IGO”), or aluminum zinc oxide (“AZO”). In another embodiment, the first electrode 221 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or compounds thereof. In another embodiment, the first electrode 221 may further include a layer formed of ITO, IZO, ZnO, or In₂O₃, above/below the reflective layer described above.

The emission layer 223 may include a polymeric or low-molecular-weight organic material that emits a certain color of light. The first functional layer 222 may include a hole transport layer (“HTL”) and/or a hole injection layer (“HIL”). The second functional layer 224 may include an electron transport layer (“ETL”) and/or an electron injection layer (“EIL”).

The second electrode 225 may include a conductive material with a low work function. For example, the second electrode 225 may include a (semi-)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), an alloy thereof, or the like. Alternatively, the second electrode 225 may further include a layer including ITO, IZO, ZnO, AZO, or In₂O₃ on the (semi-)transparent layer including the materials described above.

FIG. 7B is a cross-sectional view schematically showing a light-emitting element of a display device according to an embodiment.

Referring to FIG. 7B, a light-emitting element according to an embodiment may include an inorganic light-emitting diode 230 including an inorganic material. The inorganic light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the inorganic light-emitting diode 230 may be electrically connected to a first electrode pad 241 and a second electrode pad 242, respectively, disposed in the same layer.

In some embodiments, the first semiconductor layer 231 may include a p-type semiconductor layer. The p-type semiconductor layer may include a semiconductor material having a composition formula of InₓAl_{y}Ga_{1-x-y}N (0≤x≤1, 0≤y≤1, and 0≤x+y≤1), such as GaN, AlN, AlGaN, InGaN, InN, InAlGaN, or AlInN, and may be doped with a p-type dopant, such as Mg, Zn, Ca, Sr, or Ba.

The second semiconductor layer 232 may include, for example, an n-type semiconductor layer. The n-type semiconductor layer may include a semiconductor material having a composition formula of InₓAl_{y}Ga_{1-x-y}N (0≤x≤1, 0≤y≤1, and 0≤x+y≤1), such as GaN, AlN, AlGaN, InGaN, InN, InAlGaN, or AlInN, and may be doped with an n-type dopant, such as Si, Ge, and Sn.

The intermediate layer 233 is a region where electrons and holes recombine. As the electrons and the holes recombine, the intermediate layer 233 may transition to a lower energy level and may generate light with a wavelength corresponding thereto. For example, the intermediate layer 233 may include a semiconductor material having a composition formula of InₓAl_{y}Ga_{1-x-y}N (0≤x≤1, 0≤y≤1, and 0≤x+y≤1), and may be formed to have a single quantum well structure or a multi quantum well (“MQW”) structure. In addition, the intermediate layer 233 may include a quantum wire structure or a quantum dot structure.

Although FIG. 7B illustrates that the first semiconductor layer 231 includes a p-type semiconductor layer and the second semiconductor layer 232 includes an n-type semiconductor layer, the disclosure is not limited thereto. In another embodiment, the first semiconductor layer 231 may include an n-type semiconductor layer and the second semiconductor layer 232 may include a p-type semiconductor layer.

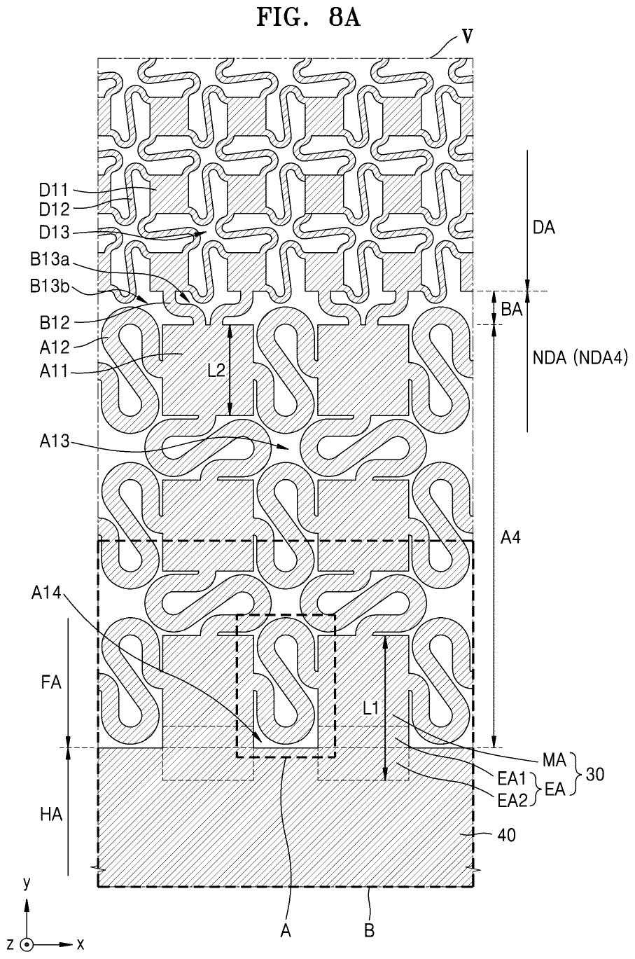

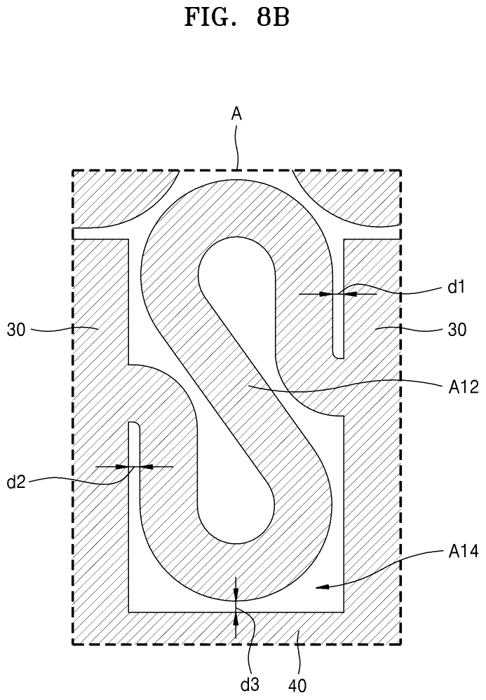

FIG. 8A is a plan view schematically showing a portion included in the display device 1 according to an embodiment and shows an area V of FIG. 3B. FIG. 8B is an enlarged plan view of an area A of FIG. 8A as a portion of the display device 1 according to an embodiment.

Referring to FIG. 8A, a hard area HA may be located on one side of a display area DA. A fourth peripheral area A4 may be located between the display area DA and the hard area HA. An intermediate area BA may be located between the display area DA and the fourth peripheral area A4. The intermediate area BA, the fourth peripheral area A4, and the hard area HA may be included in a non-display area NDA, for example, a fourth non-display area NDA4 (see FIG. 3A). The display area DA, the intermediate area BA, and the fourth peripheral area A4 may be included in a flexible area FA. In an embodiment, the hard area HA may be a “first area”, and the fourth peripheral area A4 may be a “second area”. The display device 1 may include, in the display area DA, main island portions D11 spaced apart from each other, and main bridge portions D12 spaced apart from each other by main opening portions D13 and connecting adjacent main island portions D11 to each other.

In an embodiment, the structure of the display area DA of FIG. 8A may be the same as the structure of the display area DA previously described with reference to FIG. 4C. For example, the main island portion D11, the main bridge portion D12, and the main opening portion D13 of the display area DA may correspond to the first island portion 11, the first bridge portion 12, and the first opening portion CS1 of the display area DA described with reference to FIG. 4C.

The main bridge portion D12 may have a serpentine shape. For example, the main bridge portion D12 may approximately have a shape of ‘the letter S’. Each main island portion D11 may be connected to a plurality of main bridge portions D12. For example, each main island portion D11 may be connected to two main bridge portions D12 disposed on both sides of the main island portion D11 in a first direction (e.g., x direction or −x direction) and two main bridge portions D12 disposed on both sides of the main island portion D11 in a second direction (e.g., y direction or −y direction). Each of the four main bridge portions D12 may be adjacent to each corner of the main island portion D11.

As described above with reference to FIG. 5, the main island portions D11 of the display area DA may each include light-emitting elements constituting a pixel and a pixel driving circuit portion electrically connected to the light-emitting elements. The pixel driving circuit portion may include transistors and at least one capacitor. Each of the main bridge portions D12 may include wiring lines electrically connected to pixel driving circuit portions of adjacent main island portions D11. The wiring lines electrically connected to the pixel driving circuit portions may be signal lines for providing electrical signals to transistors included in the pixel driving circuit portions or voltage lines for providing voltage. For example, data lines DL (see FIG. 6A) electrically connected to the pixel driving circuit portions may be arranged in the main bridge portion D12.

The display device 1 may include a first portion 40 in the hard area HA. The first portion 40 may have an area corresponding to the hard area HA. For example, a substrate corresponding to the first portion 40 may have an area corresponding to the hard area HA. The substrate corresponding to the first portion 40 may not have an opening in the hard area HA.

As described above with reference to FIG. 3B, the data driving circuit DDC (see FIG. 3B) and the fan-out line FWL may be arranged in the first portion 40 of the hard area HA.

The display device 1 may include, in the fourth peripheral area A4, first peripheral island portions A11 spaced apart from each other, second peripheral island portions 30 spaced apart from each other, and peripheral bridge portions A12 each connecting two adjacent island portions of the first peripheral island portions A11 and the second peripheral island portions 30. Specifically, each of the peripheral bridge portions A12 may connect a first peripheral island portion A11 and a second peripheral island portion 30, which are adjacent to each other, connect adjacent first peripheral island portions A11, or connect adjacent second peripheral island portions 30. The peripheral bridge portions A12 may be spaced apart from each other by first peripheral openings A13 between the peripheral bridge portions A12.

In an embodiment, FIG. 8A shows that two rows of first peripheral island portions A11 and one row of second peripheral island portions 30 are arranged in the fourth peripheral area A4. However, the disclosure is not limited thereto. In another embodiment, one row of second peripheral island portions 30 and one row of first peripheral island portions A11 may be arranged in the fourth peripheral area A4, or one row of second peripheral island portions 30 and three or more rows of first peripheral island portions A11 may be arranged in the fourth peripheral area A4.

The peripheral bridge portion A12 may have a serpentine shape. For example, the peripheral bridge portion A12 may approximately have a shape of ‘the letter S’. The size and/or width of the peripheral bridge portion A12 may be greater than the size and/or width of the main bridge portion D12. The radius of curvature of a round portion of the peripheral bridge portion A12 may be different from the radius of curvature of a round portion of the main bridge portion D12. For example, the radius of curvature of a round portion of the peripheral bridge portion A12 may be greater than the radius of curvature of a round portion of the main bridge portion D12.

The first peripheral island portion A11 may be connected to two peripheral bridge portions A12 disposed on both sides of the first peripheral island portion A11 in a first direction (e.g., x direction or −x direction) and two peripheral bridge portions A12 disposed on both sides of the first peripheral island portion A11 in a second direction (e.g., y direction or −y direction). Each of the four peripheral bridge portions A12 may be connected to a central portion of each side of the first peripheral island portion A11.

The second peripheral island portion 30 may be connected to two peripheral bridge portions A12 disposed on opposite sides of the second peripheral island portion 30 in the first direction (e.g., x direction or −x direction) and one peripheral bridge portion A12 disposed on one side of the second peripheral island portion 30 in the second direction (e.g., y direction). The peripheral bridge portion A12 disposed on one side of the second peripheral island portion 30 in the second direction (e.g., y direction) may be connected to a central portion of one side of the second peripheral island portion 30.

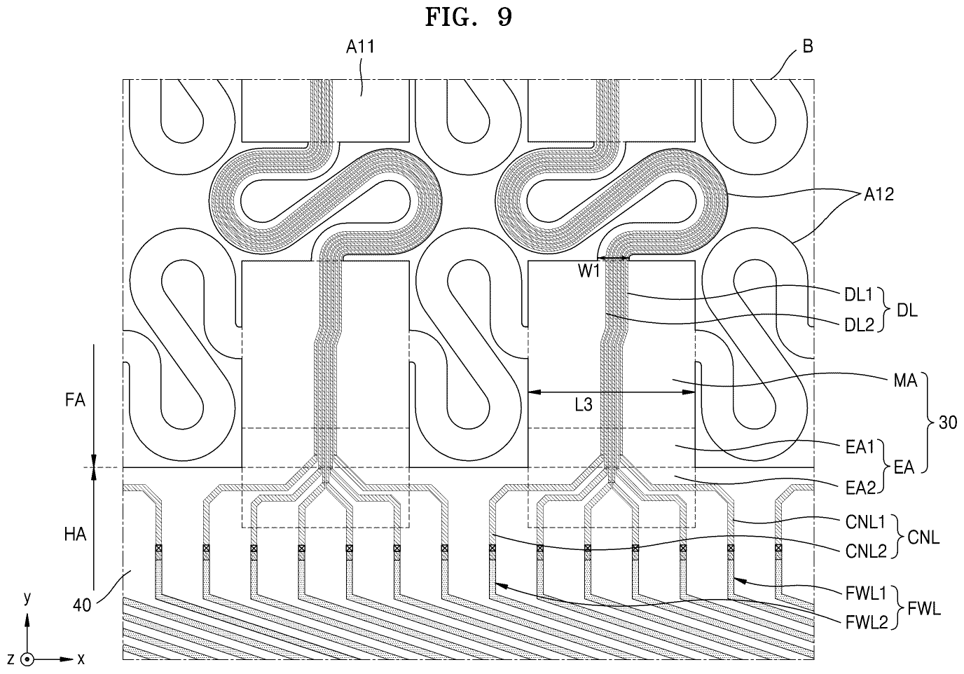

Each of the second peripheral island portions 30 may be arranged over the fourth peripheral area A4 and the hard area HA. The second peripheral island portions 30 may extend from the fourth peripheral area A4 to the hard area HA. Each of the second peripheral island portions 30 may include a main portion MA corresponding to the first peripheral island portion A11 and an extension portion EA extending from the main portion MA in the second direction (e.g., −y direction) from the fourth peripheral area A4 toward the hard area HA. The extension portion EA may include a first extension portion EA1 arranged in the fourth peripheral area A4 and a second extension portion EA2 arranged in the hard area HA. In an embodiment, the first peripheral island portion A11 and the second peripheral island portion 30 may each have a quadrangular shape. For example, the first peripheral island portion A11 and the second peripheral island portion 30 may each have a rectangular shape. The length L1 of the second peripheral island portion 30 in the second direction (e.g., −y direction) may be greater than the length L2 of the first peripheral island portion A11 in the second direction (e.g., −y direction). The length L3 of the second peripheral island portion 30 in the first direction (e.g., x direction or −x direction) may be greater than the width W1 of the peripheral bridge portion A12 (See FIG. 9). In an embodiment, the second peripheral island portions 30 may be connected to and provided integrally with the first portion 40.

The peripheral bridge portions A12 disposed on both sides of the second peripheral island portion 30 in the first direction (e.g., x direction or −x direction) may be spaced apart from each other with the first portion 40 and second peripheral openings A14 therebetween. The second peripheral openings A14 may have a different shape from the first peripheral openings A13.

Referring to FIG. 8B, a separation distance d3 between an adjacent peripheral bridge portion A12 and the first portion 40 may be equal to a separation distance between the adjacent peripheral bridge portion A12 and the second peripheral island portion 30. For example, the separation distance d3 between the adjacent peripheral bridge portion A12 and the first portion 40 may be equal to each of a separation distance d1 between the second peripheral island portion 30 on the left side (e.g., −x direction) of the peripheral bridge portion A12 and the peripheral bridge portion A12 and a separation distance d2 between the second peripheral island portion 30 on the right side (e.g., x direction) of the peripheral bridge portion A12 and the peripheral bridge portion A12. However, the disclosure is not limited thereto, and in another embodiment, the separation distance d3 between the adjacent peripheral bridge portion A12 and the first portion 40 may be different from each of the separation distance d2 between the second peripheral island portion 30 on the left side (e.g., −x direction) of the peripheral bridge portion A12 and the peripheral bridge portion A12 and the separation distance d1 between the second peripheral island portion 30 on the right side (e.g., x direction) of the peripheral bridge portion A12 and the peripheral bridge portion A12. Here, the separation distance d3 is defined as a minimum distance between an adjacent peripheral bridge portion A12 and the first portion 40 as shown in FIG. 8B, the separation distance d2 is defined as the distance between the right side of the second peripheral island portion 30 on the left side (e.g., −x direction) of the peripheral bridge portion A12 and the left side of the peripheral bridge portion A12 parallel to the right side of the second peripheral island portion 30 on the left side (e.g., −x direction) of the peripheral bridge portion A12, and the separation distance d1 is defined as the distance between the left side of the second peripheral island portion 30 on the right side (e.g., x direction) of the peripheral bridge portion A12 and the right side of the peripheral bridge portion A12 parallel to the left side of the second peripheral island portion 30 on the right side (e.g., x direction) of the peripheral bridge portion A12.

At least some of the first peripheral island portions A11, second peripheral island portions 30, and peripheral bridge portions A12 of the fourth peripheral area A4 may be dummy island portions and/or dummy bridge portions that do not include driving circuits or wiring lines, etc. Alternatively, some of the first peripheral island portions A11, second peripheral island portions 30, and peripheral bridge portions A12 may include wiring lines. For example, data lines DL (see FIG. 9) extending from the display area DA to the fourth peripheral area A4 may be arranged in some of the first peripheral island portions A11, second peripheral island portions 30, and peripheral bridge portions A12.

Referring again to FIG. 8A, intermediate bridge portions B12 may be arranged in the intermediate area BA to connect the display area DA to the fourth peripheral area A4. One end of the intermediate bridge portion B12 may be connected to the main island portion D11 and/or the main bridge portion D12, and the other end of the intermediate bridge portion B12 may be connected to the first peripheral island portion A11 and/or the peripheral bridge portion A12.

The intermediate bridge portion B12 may have a serpentine shape. In an embodiment, the shape of the intermediate bridge portion B12 may be different from the shape of the main bridge portion D12 and the shape of the peripheral bridge portion A12. The width of the intermediate bridge portion B12 may be different from the width of the main bridge portion D12 and/or the width of the peripheral bridge portion A12. For example, the width of the intermediate bridge portion B12 may be greater than the width of the main bridge portion D12 and less than the width of the peripheral bridge portion A12. First intermediate openings B13a and second intermediate openings B13b, which have different shapes, may be alternately arranged between the intermediate bridge portions B12 in the first direction (e.g., x direction or −x direction).

Wiring lines extending from the display area DA to the fourth peripheral area A4 may be arranged in the intermediate bridge portion B12 of the intermediate area BA. For example, data lines DL (see FIGS. 6A and 9) extending from the display area DA to the fourth peripheral area A4 may be arranged in the intermediate bridge portion B12.

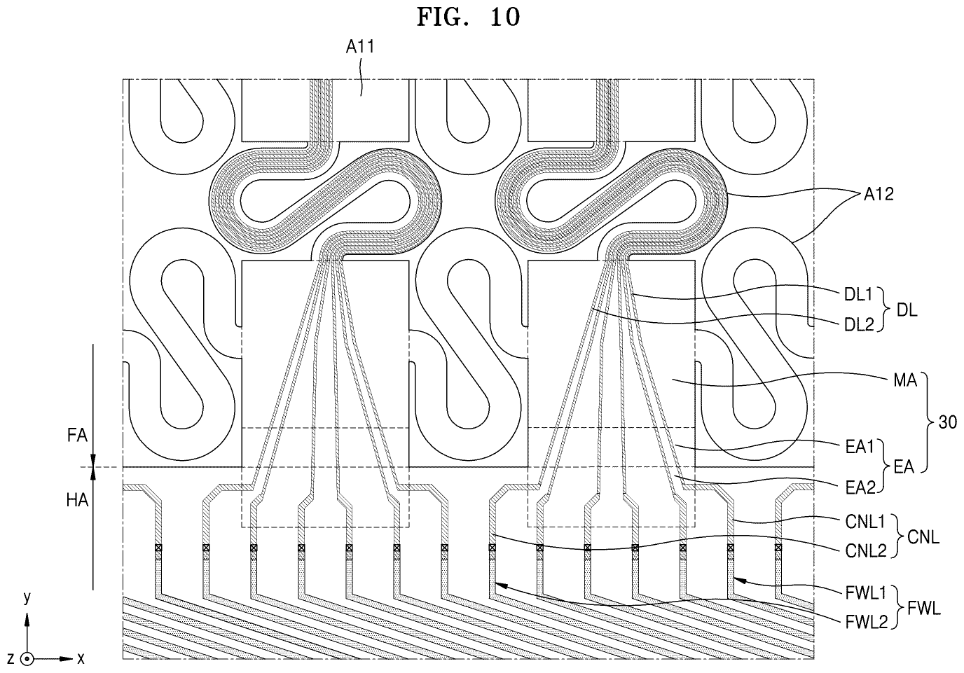

FIG. 9 is an enlarged plan view of an area B of FIG. 8A as a portion of a display device according to an embodiment. FIG. 10 is a plan view showing the area B of FIG. 8A as a portion of a display device according to another embodiment. FIG. 10 is a plan view showing a portion of the display device 1 according to an embodiment and shows a modified example of FIG. 9. FIGS. 9 and 10 show excerpts of the data line DL and fan-out line FWL included in the display device 1.

Referring to FIGS. 9 and 10, data lines DL extending from the display area DA may be arranged in the fourth peripheral area A4. The data lines DL may extend to the second peripheral island portion 30 through the first peripheral island portions A11 and the peripheral bridge portions A12. Although FIG. 10 shows six data lines DL arranged in one peripheral bridge portion A12, the disclosure is not limited thereto. In another embodiment, five or less data lines DL or seven or more data lines DL may be arranged in one peripheral bridge portion A12.

Fan-out lines FWL may be arranged in the first portion 40 of the hard area HA. The fan-out lines FWL may extend from the data driving circuit DDC (see FIG. 3B) toward the display area DA.

Because the data lines DL extend to the second peripheral island portion 30 through the peripheral bridge portion A12 having a small width, the spacing between the data lines DL extending to the second peripheral island portion 30 may be less than the spacing between the fan-out lines FWL arranged in the first portion 40. For example, the data lines DL may include a first data line DL1 and a second data line DL2, which are spaced apart from each other. The fan-out lines FWL may include a first fan-out line FWL1 and a second fan-out line FWL2, which are spaced apart from each other. As shown in FIG. 9, the spacing between the first data line DL1 and the second data line DL2 may be less than the spacing between the first fan-out line FWL1 and the second fan-out line FWL2. The data line DL and the fan-out line FWL may be electrically connected to each other through a connection line CNL. A plurality of connection lines CNL may be provided. One end of the connection line CNL may be electrically connected to the fan-out line FWL in the first portion 40. The other end of the connection line CNL may be connected to the data line DL at an extended portion EA of the second peripheral island portion 30.

For example, the connection lines CNL may each include a first connection line CNL1 and a second connection line CNL2. The first connection line CNL1 may electrically connect the first data line DL1 to the first fan-out line FWL1. The second connection line CNL2 may electrically connect the second data line DL2 to the second fan-out line FWL2.

The first connection line CNL1 may be connected to the first data line DL1 at the extended portion EA of the second peripheral island portion 30. The second connection line CNL2 may be connected to the second data line DL2 at the extended portion EA of the second peripheral island portion 30.

In an embodiment, the connection line CNL may be disposed in the same layer as the data line DL and may include the same material as the data line DL. The connection line CNL may be arranged integrally with the data line DL. In an embodiment, the connection line CNL may be disposed on a different layer from the fan-out line FWL and may be electrically connected to the fan-out line FWL through a contact hole.

In a comparative example, a peripheral bridge portion and a first portion may be connected to each other at the boundary between a flexible area and a hard area, that is, the boundary between a fourth peripheral area and the hard area, and data lines may be electrically connected to fan-out lines of the first portion through the peripheral bridge portion. In this case, because the width of the peripheral bridge portion is relatively small and a large number of data lines are arranged within the peripheral bridge portion and thus the spacing between the data lines is small, there may be insufficient space to connect the data lines to the fan-out lines at a connection portion between the peripheral bridge portion and the first portion. In addition, connection lines for connecting the data lines to the fan-out lines may be formed to be long, and the resistances of the connection lines may increase.

However, according to an embodiment, the second peripheral island portion 30 of the fourth peripheral area A4 may be connected to the first portion 40 at the boundary between the flexible area FA and the hard area HA, and the data lines DL may be electrically connected to the fan-out lines FWL of the first portion 40 through the second peripheral island portion 30. In this case, because the length L3 of the second peripheral island portion 30 in the first direction (e.g., x direction or −x direction) is greater than the width W1 of the peripheral bridge portion A12, there may be enough space to connect the data lines DL to the fan-out lines FWL at a connection portion between the data lines DL and the fan-out lines FWL, and thus, a bottleneck phenomenon may be reduced. The length of the connection line CNL may be reduced, and thus, the resistance of the connection line CNL may also be effectively reduced.

In an embodiment, the data lines DL may be arranged in a straight or diagonal line with respect to the second direction (e.g., y direction and/or −y direction) in the second peripheral island portion 30. FIG. 9 shows that the data lines DL are arranged in a straight line in the second peripheral island portion 30, while FIG. 10 shows that at least some of the data lines DL are arranged in a diagonal line in the second peripheral island portion 30.

Referring to FIG. 10, for example, the first data line DL1 is arranged in a diagonal direction inclined with respect to the second direction (e.g., y direction and/or −y direction), while the second data line DL2 may be arranged in a diagonal direction inclined with respect to the second direction (e.g., y direction and/or −y direction). In this case, compared to the case of FIG. 9, the end of the first data line DL1 in the extended portion EA of the second peripheral island portion 30 may be disposed closer to the end of the first fan-out line FWL1. The end of the second data line DL2 may be disposed closer to the end of the second fan-out line FWL2. In addition, as the first data line DL1 and the second data line DL2 extend in diagonal directions opposite to each other, the spacing between the first data line DL1 and the second data line DL2 may increase. Accordingly, the length of the first connection line CNL1 connecting the first data line DL1 to the first fan-out line FWL1 and the length of the second connection line CNL12 connecting the second data line DL2 to the second fan-out line FWL2 may be reduced. As the length of the connection line CNL decreases, the resistance of the entire wiring line may decrease. In addition, as the spacing between the data lines DL increases, there may be enough space to connect the data lines DL to the fan-out lines FWL, and thus, a bottleneck phenomenon at a connection portion between the data lines DL and the fan-out lines FWL may be further reduced.

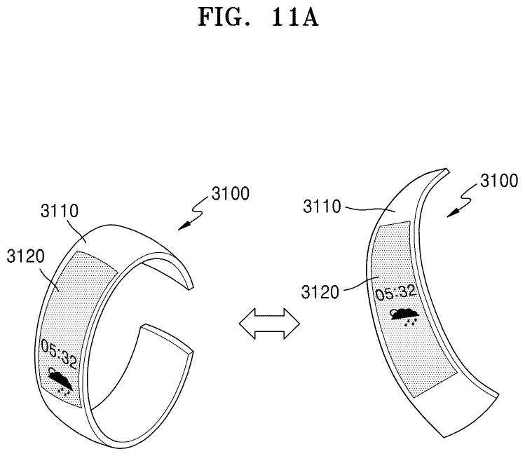

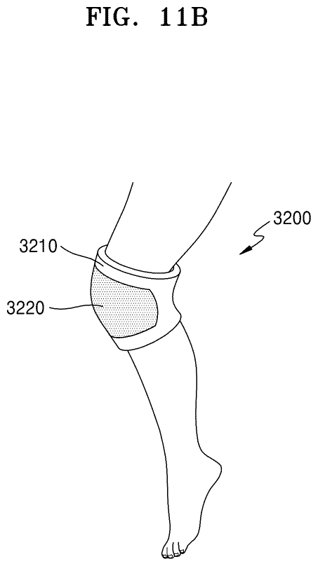

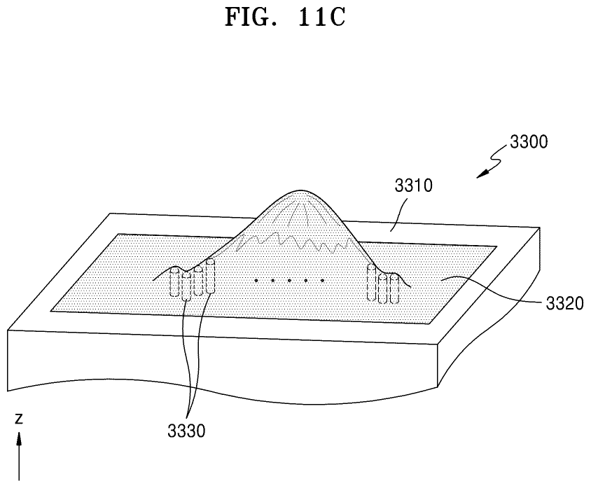

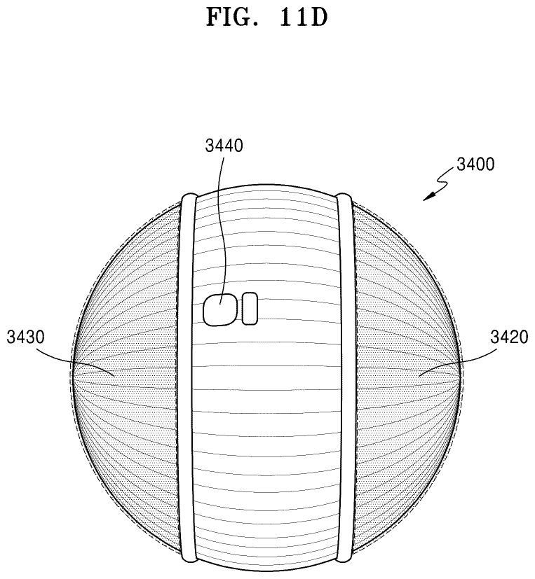

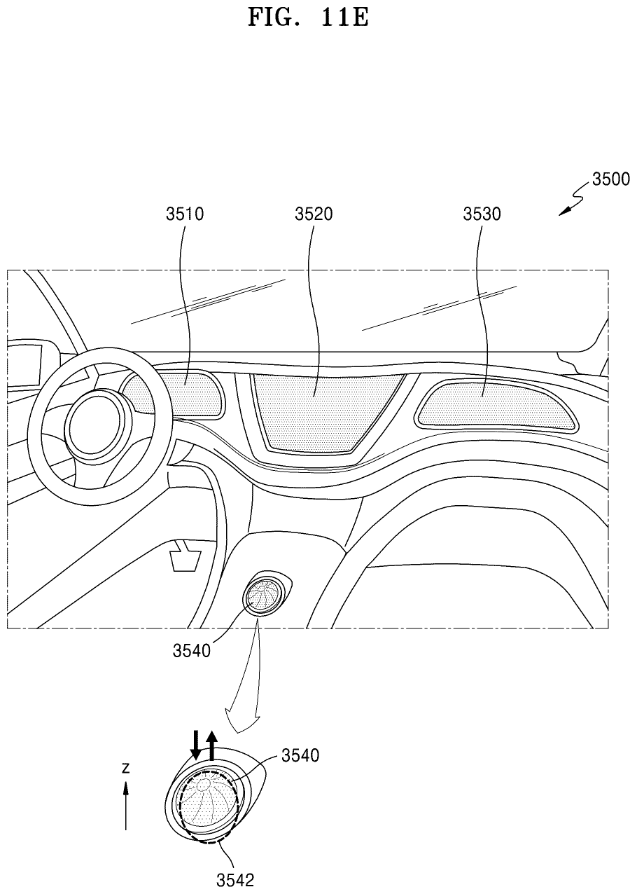

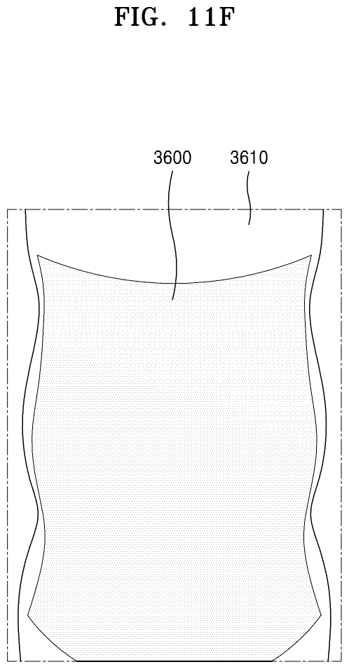

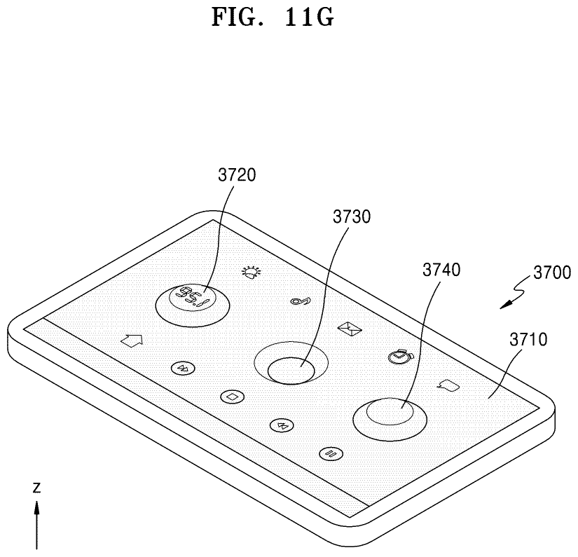

FIGS. 11A to 11G are perspective views schematically showing embodiments of an electronic device including a display device according to an embodiment.

The display device 1 according to the embodiments described above may be used in various electronic devices capable of providing images. In this case, the electronic devices refer to devices that use electricity and may provide a certain image.

Referring to FIG. 11A, the display device according to an embodiment may be used in a wearable electronic device 3100 that may be worn on a portion of a user's body. The wearable electronic device 3100 may include a body portion 3110 and a display portion 3120 provided on the body portion 3110. The display device according to an embodiment may be used as the display portion 3120 of the wearable electronic device 3100. As shown in FIG. 11A, the wearable electronic device 3100 may be deformable. In an embodiment, the wearable electronic device 3100 may be used as a smart watch or a smartphone depending on a user's choice.

FIG. 11B shows a medical electronic device 3200. In an embodiment, the medical electronic device 3200 may include a body portion 3210 and a light-emitting portion 3220. The display device according to an embodiment may be used as the light-emitting portion 3220 of the medical electronic device 3200. The light-emitting portion 3220 may emit light (e.g., infrared light or visible light) of a certain wavelength band to a patient's body. In an embodiment, the body portion 3210 may include a stretchable fiber material and may have a structure in which the body portion 3210 may be worn on a user's body.

FIG. 11C shows an educational electronic device 3300. In an embodiment, the educational electronic device 3300 may include a display portion 3320 provided within a frame 3310. The display portion 3320 may use a display device according to an embodiment. The display portion 3320 may provide images, such as an ocean with waves, a snow-covered mountain, or a volcano with flowing lava, and in this case, the display portion 3320 may be stretched in a height direction (e.g., z direction) to reflect the height of waves, mountains, or volcanoes. In some embodiments, a portion of the display portion 3320 may show the movement of lava in three dimensions by sequentially changing the height in a direction in which the lava flows. The educational electronic device 3300 may include a plurality of pins (or stroke portions) 3330 disposed on the back of the display portion 3320 so that the display portion 3320 is stretched in the height direction. As the pins 3330 move in a third direction (e.g., z direction or −z direction), the image displayed on the display portion 3320 may be implemented to have a three-dimensional height. FIG. 11C illustrates the educational electronic device 3300, but its use is not limited as long as it provides certain image information.

Although the electronic device shown in FIGS. 11A to 11C is described as an electronic device whose shape may be variable, but the disclosure is not limited thereto. As in embodiments to be described below, the display device according to embodiments may be used in an electronic device in which a part (e.g., a screen) capable of displaying an image is fixed.

FIG. 11D shows a robot 3400 as another electronic device according to an embodiment. The robot 3400 may recognize movement or objects by using a camera portion 3440 and may display a certain image to a user through display portions 3420 and 3430. In some embodiments, the display device according to an embodiment may be stretched in various directions as described above and thus may be assembled into a body frame having a hemispherical shape, and thus, the robot 3400 may include the display portions 3420 and 3430 having hemispherical shapes.

FIG. 11E shows a vehicle display device 3500 as another electronic device according to an embodiment. The vehicle display device 3500 may include a cluster 3510, a center information display (“CID”) 3520, and/or a passenger seat display 3530. Because the display device according to an embodiment may be stretched in various directions, the stretchable display device may be used in the cluster 3510, the CID 3520, and/or a co-driver display (i.e., the passenger seat display) 3530 regardless of the shape of a vehicle's internal frame.

Although FIG. 11E shows the cluster 3510, the CID 3520, and/or the co-driver display 3530 being separated, the disclosure is not limited thereto. In another embodiment, two or more selected from the cluster 3510, the CID 3520, and the co-driver display 3530 may be integrally connected.

In some embodiments, the vehicle display device 3500 may include a button 3540 that may display a certain image. Referring to the enlarged view of FIG. 11E, the button 3540 having a hemispherical shape may include an object 3542 that provides the feeling of using the button 3540 while moving in a z direction or −z direction, and a display device disposed on the object 3542. In some embodiments, when the object 3542 has a three-dimensionally rounded surface, the display device may also have a three-dimensionally rounded surface.

FIG. 11F shows that the electronic device according to an embodiment is an electronic device 3600 for advertising or exhibition. In some embodiments, the electronic device 3600 for advertising or exhibition may be installed on a fixed structure 3610, such as a wall or pillar. When the structure 3610 includes an uneven surface as shown in FIG. 11F, the electronic device 3600 for advertising or exhibition may also be arranged along the uneven surface of the structure 3610. In some embodiments, the electronic device 3600 for advertising or exhibition may be installed on the structure 3610 by using a heat-shrink film or the like.

FIG. 11G shows that the electronic device according to an embodiment is a controller 3700. The controller 3700 may include image-type buttons. For example, the controller 3700 may include first to third button areas 3720, 3730, and 3740 in which a portion of a display portion 3710 protrudes in a z direction or protrudes in a −z direction (or is dented in the z direction). In some embodiments, the first and third button areas 3720 and 3740 may protrude in the z direction, and the second button area 3730 may protrude in the −z direction (or be dented in the z direction).

According to an embodiment, a display device, which may prevent damage due to concentration of stress and may expand and contract in various directions, may be provided. The aforementioned effects are exemplary, and the scope of the disclosure is not limited by these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display device including a display area and a non-display area, wherein the non-display area includes a first area disposed on one side of the display area and a second area between the display area and the first area, the display device comprising:
a first portion arranged in the first area;
a plurality of first island portions arranged in the second area and spaced apart from each other;
a plurality of second island portions each arranged over the first area and the second area; and
a plurality of bridge portions each connecting two adjacent island portions among the plurality of first island portions and the plurality of second island portions, wherein the plurality of bridge portions are spaced apart from each other by a plurality of first openings,
wherein the plurality of second island portions are provided integrally with the first portion.

2. The display device of claim 1, further comprising:
a data driving circuit arranged in the first area; and
a fan-out line extending from the data driving circuit toward the display area.

3. The display device of claim 2, further comprising:
a data line extending from the display area to the second area; and
a connection line electrically connecting the data line to the fan-out line,
wherein the data line is connected to the connection line in the second island portion.

4. The display device of claim 3, wherein the connection line is disposed in a same layer as the data line and is provided integrally with the data line.

5. The display device of claim 1, wherein the first portion, the plurality of second island portions, and bridge portions connecting the plurality of second island portions among the plurality of bridge portions define a plurality of second openings therebetween, and the plurality of second openings have a different shape from the first openings.

6. The display device of claim 1, wherein a separation distance between the first portion and a bridge portion adjacent to the first portion among the plurality of bridge portions is equal to a separation distance between the bridge portion and a second island portion adjacent to the bridge portion among the plurality of second island portions.

7. The display device of claim 1, wherein a length of each of the plurality of second island portions in a first direction from the second area toward the first area is greater than a length of each of the plurality of first island portions in the first direction.

8. The display device of claim 7, wherein each of the plurality of bridge portions has a serpentine shape, and a length of each of the plurality of second island portions in a second direction perpendicular to the first direction is greater than a width of each of the plurality of bridge portions.

9. The display device of claim 3, wherein the data line is arranged in a straight or diagonal line with respect to a first direction from the second area toward the first area in the second island portion.

10. The display device of claim 3, further comprising:
a plurality of main island portions arranged in the display area; and
a plurality of main bridge portions each connecting adjacent main island portions among the plurality of main island portions and spaced apart from each other by a plurality of main openings,
wherein at least some of the plurality of main island portions each include a light-emitting element and a pixel circuit driver electrically connected to the light-emitting element, and the data line is electrically connected to the pixel circuit driver.

11. The display device of claim 1, wherein the first portion has an area corresponding to the first area.

12. A display device including a display area and a non-display area, wherein the non-display area includes a first area disposed on one side of the display area and a second area between the display area and the first area, the display device comprising:
a data driving circuit arranged in the first area;
a fan-out line extending from the data driving circuit toward the display area;
a data line extending from the display area to the second area;
a first portion arranged in the first area;
a plurality of first island portions arranged in the second area and spaced apart from each other;
a plurality of second island portions each arranged over the first area and the second area; and
a plurality of bridge portions each connecting two adjacent island portions among the plurality of first island portions and the plurality of second island portions, wherein the plurality of bridge portions are spaced apart from each other by a plurality of first openings,
wherein the plurality of second island portions are provided integrally with the first portion.

13. The display device of claim 12, further comprising a connection line electrically connecting the data line to the fan-out line,
wherein the data line is connected to the connection line in the second island portion.

14. The display device of claim 12, wherein the first portion, the plurality of second island portions, and bridge portions connecting the plurality of second island portions among the plurality of bridge portions define a plurality of second openings therebetween, and the plurality of second openings have a different shape from the plurality of first openings.

15. The display device of claim 12, wherein a separation distance between the first portion and a bridge portion adjacent to the first portion among the plurality of bridge portions is equal to a separation distance between the bridge portion and a second island portion adjacent to the bridge portion among the plurality of second island portions.

16. The display device of claim 12, wherein a length of each of the plurality of second island portions in a first direction from the second area toward the first area is greater than a length of each of the plurality of first island portions in the first direction.

17. The display device of claim 16, wherein each of the plurality of bridge portions has a serpentine shape, and a length of each of the plurality of second island portions in a second direction perpendicular to the first direction is greater than a width of each of the plurality of bridge portions.

18. The display device of claim 12, wherein the data line is arranged in a straight or diagonal line with respect to a first direction from the second area toward the first area in the second island portion.

19. The display device of claim 12, further comprising:
a plurality of main island portions arranged in the display area; and
a plurality of main bridge portions each connecting adjacent main island portions among the plurality of main island portions and spaced apart from each other by a plurality of main openings,
wherein at least some of the plurality of main island portions each include a light-emitting element and a pixel circuit driver electrically connected to the light-emitting element, and the data line is electrically connected to the pixel circuit driver.

20. The display device of claim 12, wherein the first portion has an area corresponding to the first area.
